(19) United States
(12) Patent Application Publication
(10) Pub. No.: US 2011/0260239 A1
(43) Pub. Date: Oct. 27, 2011

(54) SEMICONDUCTOR DEVICE AND METHOD OF FABRICATING THE SAME

(75) Inventor: Kiyonori OYU, Tokyo (JP)

(73) Assignee: ELPIDA MEMORY, INC., Tokyo (JP)

(21) Appl. No.: 13/085,897

(22) Filed: Apr. 13, 2011

(30) Foreign Application Priority Data
Apr. 22, 2010 (JP) 2010-098835

(51) Int. Cl. H01L 29/78

(52) U.S. Cl. 257/330; 257/E29.262

(57) ABSTRACT

A semiconductor device includes a first capacitive insulating film, a semiconductor region, a gate insulating film, and a gate electrode. The semiconductor region has a groove. The gate insulating film covers a surface of the groove. The gate electrode is in the groove. The gate electrode includes first and second conductive films. The first conductive film is in contact with the gate insulating film. The first conductive film has an upper surface which is higher than a close portion of the second conductive film. The close portion is closer to the upper surface of the first conductive film.

### BACKGROUND OF THE INVENTION

1. Field of the Invention

The present invention relates to a semiconductor device and a method of fabricating the same.

Priority is claimed on Japanese Patent Application No. 2010-098835, Apr. 22, 2010, the content of which is incorporated herein by reference.

2. Description of the Related Art

Japanese Unexamined Patent Application, First Publication, No. JP-A-2001-210801 discloses a metal oxide semiconductor (MOS) transistor including the following elements. A groove is formed in a semiconductor substrate. A gate insulating film is formed in the groove. A gate electrode is provided in the groove (a buried gate electrode). An insulating film is buried in a groove formed on the gate electrode to reach a surface of the semiconductor substrate. A first impurity diffusion layer is formed in the semiconductor substrate. The first impurity diffusion layer is disposed at one side of the groove. A second impurity diffusion layer is formed in the semiconductor substrate. The second impurity diffusion layer is disposed at the other side of the groove.

The MOS transistor described above operates by applying turn-on potential to the gate electrode while drain voltage is applied to one of the impurity diffusion layer functioning as a drain region and a source voltage is applied to the other impurity diffusion layer functioning as a source region, such that a channel region is formed in a sidewall and a bottom of the groove.

With miniaturization of the MOS transistor in recent years, low resistance of a gate electrode has been required. Conductive materials such as metals, metal silicides, and metal nitrides have been used as a material for the gate electrode with the low resistance.

From the perspective of improvement of control of a threshold voltage of a MOS transistor, conductive materials, such as metals, metal silicides, and metal nitrides, having a predetermined work function have been used as a material for the gate electrode.

A representative example of the gate electrode formed of a metal film includes a gate electrode that is formed of a titanium nitride film formed to contact a gate insulating film and a tungsten film formed on a surface of the titanium nitride film to be buried in a portion of a groove.

Titanium nitride has a work function of about 4.75 eV. The value of work function of titanium nitride is near the value of the mid-gap of the silicon band structure. The titanium nitride film between a tungsten film and a gate insulating film has relatively high resistivity. The titanium nitride film can suppress tungsten atoms in the tungsten film from moving through the titanium nitride film to the gate insulating film. The tungsten film has a lower resistivity of 5 μΩcm and contributes to reduce the resistance of the gate electrode.

### SUMMARY

In one embodiment, a semiconductor device may include, but is not limited to, a semiconductor region, a gate insulating film, and a gate electrode. The semiconductor region has a groove. The gate insulating film covers a surface of the groove. The gate electrode is in the groove. The gate electrode includes first and second conductive films. The first conductive film is in contact with the gate insulating film. The first conductive film has an upper surface which is higher than a close portion of the second conductive film. The close portion is closer to the upper surface of the first conductive film.

In another embodiment, a semiconductor device may include, but is not limited to, a semiconductor region, a gate insulating film, a gate electrode, and an insulating film. The semiconductor region has a groove. The gate insulating film covers a surface of the groove. The gate electrode is in the groove. The gate electrode includes first and second conductive films. The first conductive film is in contact with the gate insulating film. The first conductive film includes an upper portion. The upper portion has an upper side surface. The insulating film covers the second conductive film. The insulating film has a first side surface which faces to the upper side surface.

In still another embodiment, a semiconductor device may include, but is not limited to, a semiconductor region and a gate electrode. The semiconductor region has a semiconductor side surface. The gate electrode includes first and second conductive films. The first conductive film extends along the semiconductor side surface. The second conductive film is disposed near the first conductive film. A top of the first conductive film is higher than a top of the second conductive film.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a fragmentary cross sectional elevation view illustrating a semiconductor device in accordance with one embodiment of the present invention;

FIG. 2 is a fragmentary cross sectional elevation view, taken along an A-A line of FIG. 1, illustrating the semiconductor device in accordance with one embodiment of the present invention;

FIG. 3 is a fragmentary cross sectional elevation view illustrating the semiconductor device in accordance with one embodiment of the present invention;

FIG. 4 is a fragmentary cross sectional elevation view illustrating a transistor in a step involved in a method of forming the semiconductor device of FIG. 2 in accordance with one embodiment of the present invention;

FIG. 5 is a fragmentary cross sectional elevation view illustrating the transistor in a step, subsequent to the step of FIG. 4, involved in a method of forming the semiconductor device of FIG. 1 in accordance with one embodiment of the present invention;

FIG. 6 is a fragmentary cross sectional elevation view illustrating the transistor in a step, subsequent to the step of FIG. 5, involved in a method of forming the semiconductor device of FIG. 1 in accordance with one embodiment of the present invention;

FIG. 7 is a fragmentary cross sectional elevation view illustrating the transistor in a step, subsequent to the step of FIG. 6, involved in a method of forming the semiconductor device of FIG. 1 in accordance with one embodiment of the present invention;

FIG. 8 is a fragmentary cross sectional elevation view illustrating the transistor in a step, subsequent to the step of FIG. 7, involved in a method of forming the semiconductor device of FIG. 1 in accordance with one embodiment of the present invention;

FIG. 9 is a fragmentary cross sectional elevation view illustrating the transistor in a step, subsequent to the step of FIG. 8, involved in a method of forming the semiconductor device of FIG. 1 in accordance with one embodiment of the present invention;

FIG. 10 is a fragmentary cross sectional elevation view illustrating the transistor in a step, subsequent to the step of FIG. 9, involved in a method of forming the semiconductor device of FIG. 1 in accordance with one embodiment of the present invention;

FIG. 11 is a fragmentary cross sectional elevation view illustrating the transistor in a step, subsequent to the step of FIG. 10, involved in a method of forming the semiconductor device of FIG. 1 in accordance with one embodiment of the present invention;

FIG. 12 is a fragmentary cross sectional elevation view illustrating the transistor in a step, subsequent to the step of FIG. 11, involved in a method of forming the semiconductor device of FIG. 1 in accordance with one embodiment of the present invention;

FIG. 13 is a fragmentary cross sectional elevation view illustrating the transistor in a step, subsequent to the step of FIG. 12, involved in a method of forming the semiconductor device of FIG. 1 in accordance with one embodiment of the present invention;

FIG. 14 is a fragmentary cross sectional elevation view illustrating the transistor in a step, subsequent to the step of FIG. 13, involved in a method of forming the semiconductor device of FIG. 1 in accordance with one embodiment of the present invention;

FIG. 15 is a fragmentary cross sectional elevation view illustrating the transistor in a step, subsequent to the step of FIG. 14, involved in a method of forming the semiconductor device of FIG. 1 in accordance with one embodiment of the present invention;

FIG. 16 is a fragmentary cross sectional elevation view illustrating the transistor in a step, subsequent to the step of FIG. 15, involved in a method of forming the semiconductor device of FIG. 1 in accordance with one embodiment of the present invention;

FIG. 17 is a fragmentary cross sectional elevation view illustrating a semiconductor device in accordance with another embodiment of the present invention;

FIG. 18 is a fragmentary cross sectional elevation view, taken along a B-B line of FIG. 17, illustrating the semiconductor device in accordance with another embodiment of the present invention;

FIG. 19 is a fragmentary cross sectional elevation view, taken along a C-C line of FIG. 17, illustrating the semiconductor device in accordance with another embodiment of the present invention;

FIG. 20 is a fragmentary cross sectional elevation view, taken along a D-D line of FIG. 17, illustrating the semiconductor device in accordance with another embodiment of the present invention;

FIG. 21 is a fragmentary cross sectional elevation view illustrating a transistor in a step involved in a method of forming the semiconductor device of FIG. 17 in accordance with another embodiment of the present invention;

FIG. 22 is a fragmentary cross sectional elevation view illustrating the transistor in a step, subsequent to the step of FIG. 21, involved in the method of forming the semiconductor device of FIG. 17 in accordance with another embodiment of the present invention;

FIG. 23 is a fragmentary cross sectional elevation view illustrating the transistor in a step, subsequent to the step of FIG. 22, involved in the method of forming the semiconductor device of FIG. 17 in accordance with another embodiment of the present invention;

FIG. 24 is a fragmentary cross sectional elevation view illustrating the transistor in a step, subsequent to the step of FIG. 23, involved in the method of forming the semiconductor device of FIG. 17 in accordance with another embodiment of the present invention;

FIG. 25 is a fragmentary cross sectional elevation view illustrating the transistor in a step, subsequent to the step of FIG. 24, involved in the method of forming the semiconductor device of FIG. 17 in accordance with another embodiment of the present invention;

FIG. 26 is a fragmentary cross sectional elevation view illustrating the transistor in a step, subsequent to the step of FIG. 25, involved in the method of forming the semiconductor device of FIG. 17 in accordance with another embodiment of the present invention;

FIG. 27 is a fragmentary cross sectional elevation view illustrating the transistor in a step, subsequent to the step of FIG. 26, involved in the method of forming the semiconductor device of FIG. 17 in accordance with another embodiment of the present invention;

FIG. 28 is a fragmentary cross sectional elevation view illustrating the transistor in a step, subsequent to the step of FIG. 27, involved in the method of forming the semiconductor device of FIG. 17 in accordance with another embodiment of the present invention;

FIG. 29 is a fragmentary cross sectional elevation view illustrating the transistor in a step, subsequent to the step of FIG. 28, involved in the method of forming the semiconductor device of FIG. 17 in accordance with another embodiment of the present invention;

FIG. 30 is a fragmentary cross sectional elevation view illustrating the transistor in a step, subsequent to the step of FIG. 29, involved in the method of forming the semiconductor device of FIG. 17 in accordance with another embodiment of the present invention;

FIG. 31 is a fragmentary cross sectional elevation view illustrating the transistor in a step, subsequent to the step of FIG. 30, involved in the method of forming the semiconductor device of FIG. 17 in accordance with another embodiment of the present invention;

FIG. 32 is a fragmentary cross sectional elevation view illustrating a buried gate electrode in a step involved in a method of forming the semiconductor device in accordance with the related art;

FIG. 33 is a fragmentary cross sectional elevation view illustrating a buried gate electrode in a step, subsequent to the step of FIG. 32, involved in the method of forming the semiconductor device in accordance with the related art;

FIG. 34 is a fragmentary cross sectional elevation view illustrating a buried gate electrode in a step, subsequent to the step of FIG. 33, involved in the method of forming the semiconductor device in accordance with the related art; and

FIG. 35 is a fragmentary cross sectional elevation view illustrating a buried gate electrode in a step, subsequent to the step of FIG. 34, involved in the method of forming the semiconductor device in accordance with the related art.

### DETAILED DESCRIPTION OF THE PREFERRED EMBODIMENTS

Before describing the present invention, the related art will be explained in detail, in order to facilitate the understanding of the present invention.

The buried gate electrode may be formed by using, for example, the titanium nitride film and the tungsten film described above.

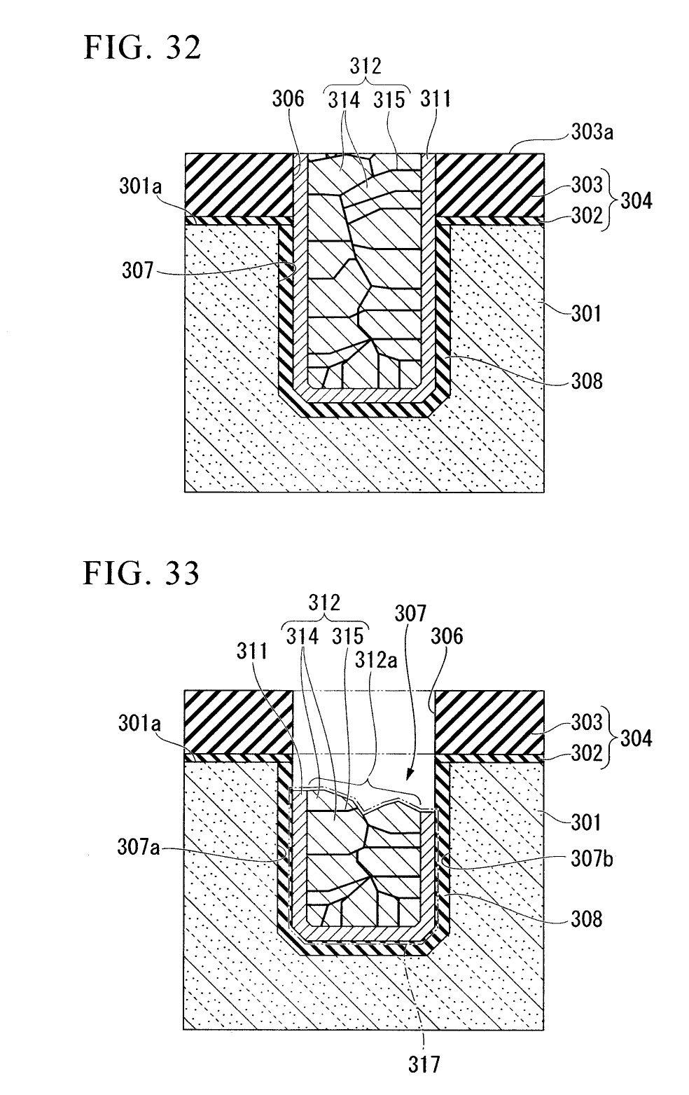

FIGS. 32 to 35 are fragmentary cross sectional elevation views illustrating a buried gate electrode in steps involved in a method of forming the semiconductor device in accordance with the related art. The method is to form the buried gate electrode. FIGS. 32 to 35 schematically show crystal grains 314 of a tungsten film 312 and these boundaries 315.

The method of forming the buried gate electrode of the related art will be apparent from descriptions with reference to FIGS. 32 to 35.

As shown in FIG. 32, an etching mask 304 is formed of a silicon oxide film 302 and a silicon nitride film 303. The etching mask has a through hole 306. The etching mask is formed on a surface 301a of a semiconductor substrate 301. A part of the semiconductor substrate 301 shown through the through hole 306 is then etched to form a groove 307 in the semiconductor substrate 301.

A gate insulating film 308 is then formed to cover the groove 307. Then, a titanium nitride film 311 is formed to cover a side surface of the through hole 306 and the gate insulating film 308 formed in the groove 307. A tungsten film 312 is formed to fill the through hole 306 and the groove 307 in which the titanium nitride film 311 is formed. The tungsten film 312 includes a plurality of crystal grains 314 and crystal grain boundaries 315 disposed between the crystal grains 314. The plurality of crystal grains 314 have differences in size or shape. The crystal grain boundaries 315 have a higher etching rate than the crystal grains 314.

Unnecessary titanium nitride and tungsten films 311 and 312 (both not shown) formed on a surface 303a of the silicon nitride film 303 are then removed by polishing of the chemical mechanical polishing (CMP) method to form a structure shown in FIG. 32.

As shown in FIG. 33, an etch-back process of the titanium nitride film 311 and the tungsten film 312 formed in the through hole 306 and the groove 307 is performed up to a predetermined depth, thereby forming a gate electrode 317 in the groove 307. The gate electrode 317 includes the titanium nitride film 311 and the tungsten film 312.

In this case, an etching rate is not uniform in the etch-back process of the gate electrode 317 due to the crystal grain boundaries 315 of the tungsten film 312, which causes non-flatness of a surface 312a of the etched tungsten film 312 and a difference of depths of the gate electrode 317 from the surface 301a of the semiconductor substrate 301.

Non-uniform etching rate will cause the gate electrode 317 to have an asymmetrical shape. The gate electrode 317 has different heights at different positions. The gate electrode 317 has a first height at its first side contacting with a side surface 307a of the groove 307. The gate electrode 317 has a second height at its second side contacting with a side surface 307b of the groove 307. The first and second heights are so different that the gate electrode has an offset structure.

When the etch-back process of the titanium nitride film 311 and the tungsten film 312 is performed, tungsten atoms included in the tungsten film 312 reach the semiconductor substrate 301 through the gate insulating film 308 which is not covered by the titanium nitride film 311, thereby causing increased junction leakage current.

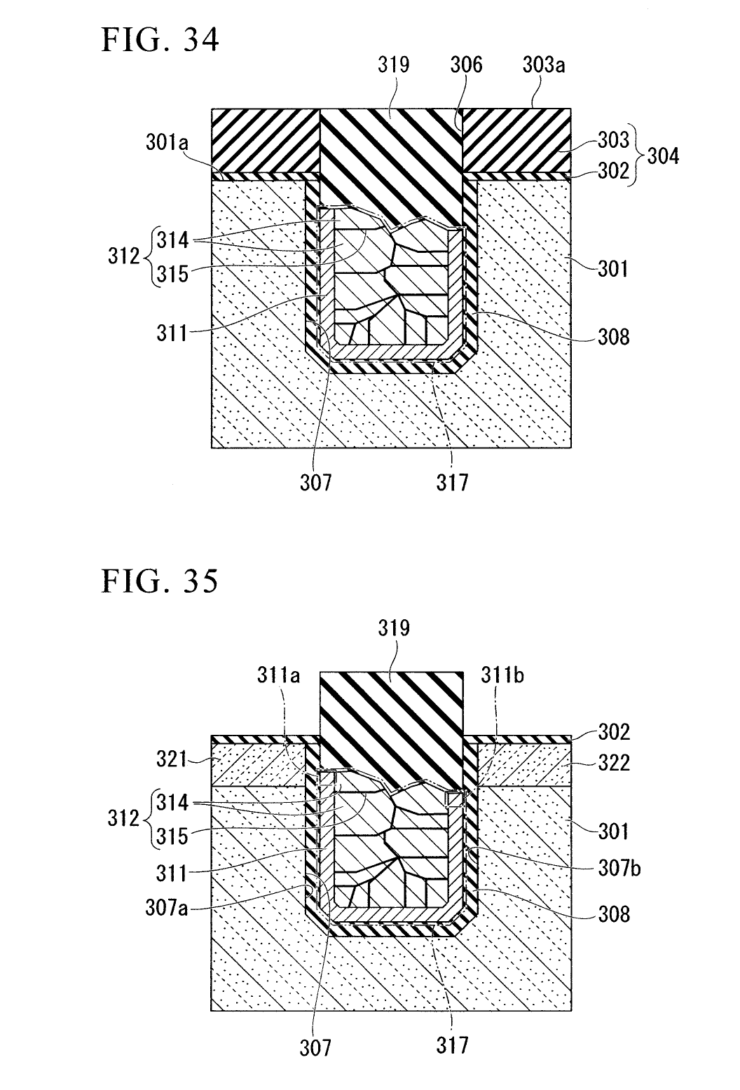

In a process shown in FIG. 34, an insulating film 319 is then formed to be buried in the groove 307 and the through hole 306 in which the gate electrode 317 is formed. The insulating film 319 is formed, for example, as follows. The insulating film 319 is deposited on the upper surface of the structure shown in FIG. 33. An unnecessary portion of the insulating film 319 (not shown) located on the surface 303a of the silicon nitride film 303 is then removed by CMP. In this case, the silicon nitride film 303 is used as a polishing stopper film.

In a process shown in FIG. 35, the silicon nitride film 303 shown in FIG. 34 is then removed. Then, an impurity is introduced into the semiconductor substrate 301 through the silicon oxide film 302 and annealed to form first and second impurity diffusion layers 321 and 322.

Here, the height of the gate electrode 317 at the side surface 307a of the groove 307 differs from the height of the gate electrode 317 at the side surface 307b of the groove 307 as described above. Therefore, for example, a structure in which one upper end portion 311a of the titanium nitride film 311 faces the first impurity diffusion layer 321 and the other upper end portion 311b of the titanium nitride film 311 does not face the second impurity diffusion layer 322 (offset structure) may be obtained, as shown in FIG. 35.

Thereby, characteristics and properties of the semiconductor device are asymmetrical. Thus, desired drive current of the semiconductor device are not obtainable.

When the gate electrode 317 is formed by the above-described method, the upper end portions 311a and 311b of the titanium nitride film 311 is asymmetrical to the left and right of the groove 307. The upper end portion 311b of the titanium nitride film 311 does not face the second impurity diffusion layer 322. Desired characteristics and properties of the semiconductor device are not obtainable and the characteristics and the properties are different among different products of the semiconductor device.

Even when a conductive film that includes the crystal grain 314 and the crystal grain boundaries 315, like the tungsten film, were used in place of the tungsten film 312, the desired characteristics and properties would not be obtainable.

Embodiments of the invention will be now described herein with reference to illustrative embodiments. Those skilled in the art will recognize that many alternative embodiments can be accomplished using the teaching of the embodiments of the present invention and that the invention is not limited to the embodiments illustrated for explanatory purpose.

In one embodiment, a semiconductor device may include, but is not limited to, a semiconductor region, a gate insulating film, and a gate electrode. The semiconductor region has a groove. The gate insulating film covers a surface of the groove. The gate electrode is in the groove. The gate electrode includes first and second conductive films. The first conductive film is in contact with the gate insulating film. The first conductive film has an upper surface which is higher than a close portion of the second conductive film. The close portion is closer to the upper surface of the first conductive film.

In some cases, the semiconductor device may include, but is not limited to, the first conductive film being interposed between the gate insulating film and the second conductive film.

In some cases, the semiconductor device may further include, but is not limited to, an insulating film in the groove. The insulating film covers the second conductive film.

In some cases, the semiconductor device may include, but is not limited to, the upper surface of the first conductive film having a substantially uniform level.

In some cases, the semiconductor device may include, but is not limited to, a top of the second conductive film being lower than the upper surface of the first conductive film.

In some cases, the semiconductor device may include, but is not limited to, an upper surface of the insulating film being substantially the same in level as the upper surface of the first conductive film.

In some cases, the semiconductor device may include, but is not limited to, the second conductive film being lower in resistivity than the first conductive film.

In some cases, the first conductive film may further include, but is not limited to, first and second portions. The first and second portions are positioned at opposite sides of the first conductive film. A first upper surface of the first portion is substantially the same in level as a second upper surface of the second portion.

In some cases, the semiconductor device may include, but is not limited to, the second conductive film being greater in horizontal dimension than the first conductive film.

In some cases, the semiconductor device may include, but is not limited to, an upper surface of the second conductive film being non-flat.

In some cases, the semiconductor device may include, but is not limited to, the second conductive film having crystal grains and grain boundaries.

In some cases, the semiconductor device may further include, but is not limited to, a first impurity diffusion layer in the semiconductor region. The first impurity diffusion layer is adjacent to the groove. The first impurity diffusion layer has a top portion and a bottom portion. The upper surface of the first conductive film is higher than the bottom portion and lower than the top portion.

In some cases, the semiconductor device may further include, but is not limited to, a third conductive film between the first and second conductive films.

In another embodiment, a semiconductor device may include, but is not limited to, a semiconductor region, a gate insulating film, a gate electrode, and an insulating film. The semiconductor region has a groove. The gate insulating film covers a surface of the groove. The gate electrode is in the groove. The gate electrode includes first and second conductive films. The first conductive film is in contact with the gate insulating film. The first conductive film includes an upper portion. The upper portion has an upper side surface. The insulating film covers the second conductive film. The insulating film has a first side surface which faces to the upper side surface.

In some cases, the semiconductor device may include, but is not limited to, an upper surface of the insulating film being substantially the same in level as an upper surface of the first conductive film.

In some cases, the semiconductor device may include, but is not limited to, an upper surface of the second conductive film being non-flat.

In some cases, the semiconductor device may include, but is not limited to, the second conductive film being greater in horizontal dimension than the first conductive film.

In still another embodiment, a semiconductor device may include, but is not limited to, a semiconductor region and a gate electrode. The semiconductor region has a semiconductor side surface. The gate electrode includes first and second conductive films. The first conductive film extends along the semiconductor side surface. The second conductive film is disposed near the first conductive film. A top of the first conductive film is higher than a top of the second conductive film.

In some cases, the semiconductor device may further include, but is not limited to, an insulating film in the groove. The insulating film covers the second conductive film.

In some cases, the semiconductor device may include, but is not limited to, an upper surface of the insulating film being substantially the same in level as an upper surface of the first conductive film.

Hereinafter, a semiconductor device according to an embodiment of the invention will be described in detail with reference to the drawings. In the drawings used for the following description, to easily understand characteristics, there is a case where characteristic parts are enlarged and shown for convenience' sake, and ratios of constituent elements may not be the same as in reality. Materials, sizes, and the like exemplified in the following description are just examples. The invention is not limited thereto and may be appropriately modified within a scope which does not deviate from the concept of the invention.

### First Embodiment

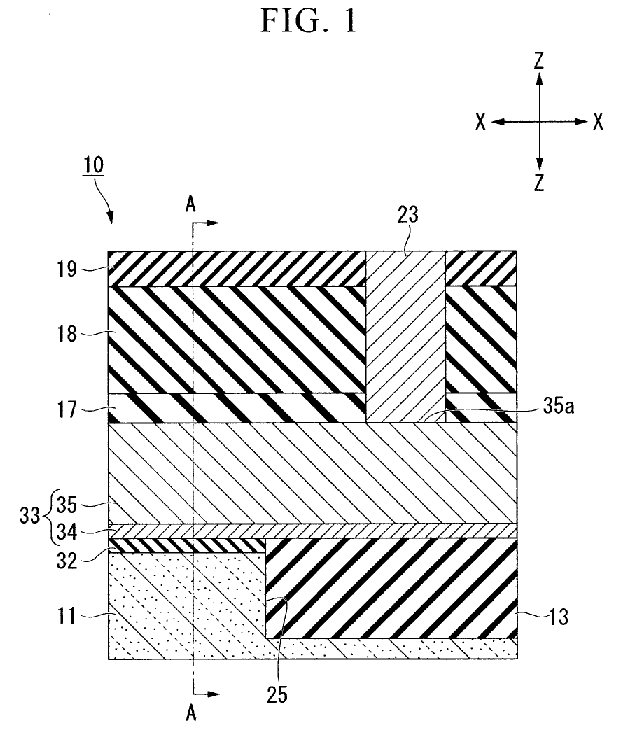

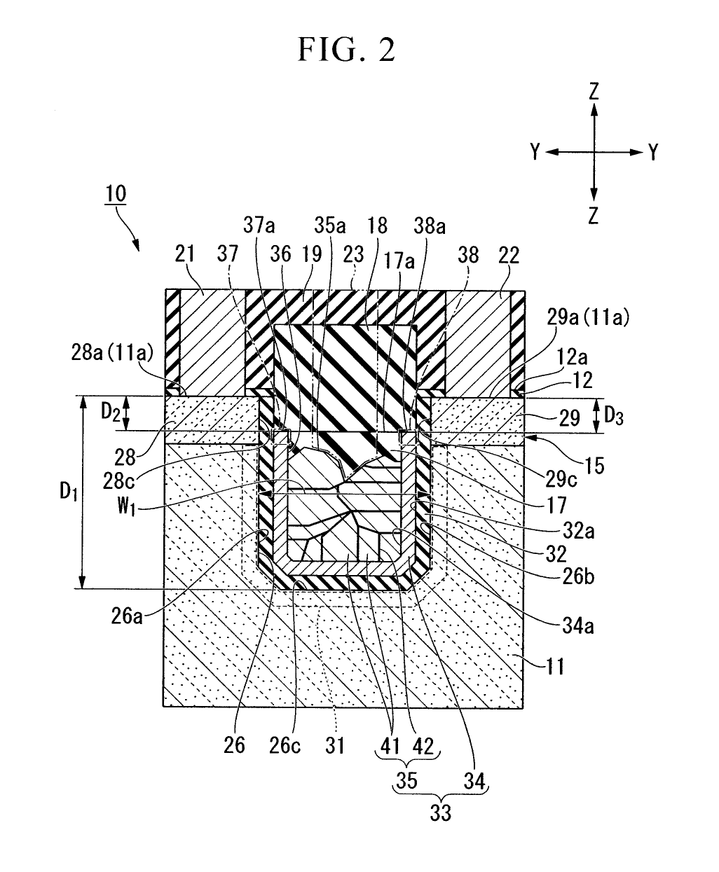

FIG. 1 is a fragmentary cross sectional elevation view illustrating a semiconductor device in accordance with one embodiment of the present invention, and FIG. 2 is a fragmentary cross sectional elevation view, taken along an A-A line of FIG. 1, illustrating the semiconductor device shown in FIG. 1.

A second conductive film 35 shown in FIG. 1 has the same structure as a second conductive film 35 schematically shown in FIG. 2. Specifically, the second conductive film 35 has a structure having a plurality of crystal grains 41 and crystal grain boundaries 42. However, in the second conductive film 35 shown in FIG. 1, the plurality of crystal grains 41 and the crystal grain boundaries 42 shown in FIG. 2 are not shown.

FIG. 2 illustrates a transistor 15 but, in fact, a plurality of transistors 15 are provided in the semiconductor device 10.

In FIGS. 1 and 2, Z-Z represents a depth direction of a second groove 26, X-X represents a direction perpendicular to the direction Z-Z, and Y-Y represents a direction perpendicular to the direction X-X in the same plane. In FIG. 2, the same components as those shown in FIG. 1 are indicated by the same reference numerals.

Referring to FIGS. 1 and 2, the semiconductor device 10 of the first embodiment may include, but is not limited to, a semiconductor substrate 11, a third insulating film 12, an isolation region 13, a transistor 15, a first insulating film 17, a second insulating film 18, an interlayer insulating film 19, a first contact plug 21, a second contact plug 22, and a third contact plug 23.

The semiconductor substrate 11 is a plate-shaped substrate. A first groove 25 and a second groove 26 are formed in the semiconductor substrate 11. The isolation region 13 is formed in the first groove 25. The second groove 26 extends in the direction X-X.

The second groove 26 is formed by partially etching a surface 11a of the semiconductor substrate 11. The surface 11a is a main surface of the semiconductor substrate 11. The second groove 26 has an inner surface including first and second side surfaces 26a and 26b, which are vertical, and a bottom 26c. A depth D₁ of the second groove 26 is smaller than a depth of the first groove 25.

The depth D₁ of the second groove 26 from the surface 11a of the semiconductor substrate 11 may be, but is not limited to, 150 nm. Further, the width W₁ of the second groove 26 may be, but is not limited to, 60 nm. The width W₁ and the depth D₁ of the second groove 26 may be properly selected according to desired characteristics of the transistor 15 and are not limited to the above values.

For example, a P-type silicon substrate may be used as the semiconductor substrate 11. In this case, the concentration of boron, which is a P-type impurity contained in the semiconductor substrate 11, may be, but is not limited to, 1.0×10¹⁷ atoms/cm³, for example. The concentration of boron may be adjusted to obtain a predetermined threshold voltage.

The third insulating film 12 covers the surface 11a of the semiconductor substrate 11. For example, a silicon oxide film (SiO₂ film) with a thickness of 10 nm may be used as the third insulating film 12.

The isolation region 13 is buried in the first groove 25. The isolation region 13 is formed of an insulating film (e.g., a silicon oxide film (SiO₂ film)).

The transistor 15 may be a metal oxide semiconductor (MOS) transistor. The transistor 15 includes a first impurity diffusion layer 28, a second impurity diffusion layer 29, a channel region 31, a gate insulating film 32, and a gate electrode 33.

The first and second impurity diffusion layers 28 and 29 are impurity diffusion layers, one functioning as a source region and the other functioning as a drain region. The first and second impurity diffusion layers 28 and 29 are formed in the surface 11a of the semiconductor substrate 11 and the vicinity thereof. Surfaces 28a and 29a of the first and second impurity diffusion layers 28 and 29 are substantially the same in level as the surface 11a of the semiconductor substrate 11.

The first impurity diffusion layer 28 is disposed at the first side surface 26a of the second groove 26. A side surface 28c of the first impurity diffusion layer 28 forms a part of the side surface 26a of the second groove 26.

The second impurity diffusion layer 29 is disposed at the second side surface 26b of the second groove 26. The second side surface 26b and the first side surface 26a are positioned at opposite sides of the second groove 26. A side surface 29c of the second impurity diffusion layer 29 forms a part of the side surface 26b of the second groove 26.

The depth of the bottom portion of each of the first and second impurity diffusion layers 28 and 29 is greater than second and third depths D₂ and D₃. The second depth D₂ is a distance from the surface of the substrate 11 to a upper surface 37a of a first conductive film 34. The third depth D₃ is a distance from the surface of the substrate 11 to a upper surface 38a of the first conductive film 34. Each of the first and second diffusion layers 28 and 29 has a top portion and a bottom portion. The upper surface of the first conductive film 34 is higher than the bottom portion and lower than the top portion.

When the semiconductor substrate 11 is a P-type silicon substrate, the first and second impurity diffusion layers 28 and 29 may be formed by ion-implanting an N-type impurity into the surface 11a of the semiconductor substrate 11.

The depths of the first and second impurity diffusion layers 28 and 29 from the surface 11a of the semiconductor substrate 11 are substantially the same. The depths of the first and second impurity diffusion layers 28 and 29 from the surface 11a of the semiconductor substrate 11 may be, but is not limited to, 45 nm.

The channel region 31 is formed in a vicinity of the side surfaces 26a and 26b and the bottom 26c of the second groove 26 in the semiconductor substrate 11 when the transistor 15 is turned ON.

The gate insulating film 32 covers the first and second side surfaces 26a and 26b and the bottom 26c of the second groove 26, the side surface 28c of the first impurity diffusion layer 28, and the side surface 29c of the second impurity diffusion layer 29. The gate insulating film 32 may be realized by, but not limited to, a single layer silicon oxide film (SiO₂ film), a film obtained by nitriding a silicon oxide film (SiON film), a stacked silicon oxide film (SiO₂ film), and a stacked film obtained by stacking a silicon nitride film (SiN film) on a silicon oxide film (SiO₂ film).

In some cases, when the single layer silicon oxide film (SiO₂ film) is used as the gate insulating film 32, a thickness of the gate insulating film 32 may be, but is not limited to, 6 nm.

The gate electrode 33 includes a first conductive film 34, a second conductive film 35, and a space 36.

The first conductive film 34 determines a threshold voltage of the transistor 15. The first conductive film 34 is a film functioning as a barrier film for preventing heavy-metal atoms contained in the second conductive film 35 (specifically, tungsten atoms when the second conductive film 35 is a tungsten film) from reaching the gate insulating film 32. The heavy-metal atoms adversely affect characteristics of the transistor 15 when diffused into the semiconductor substrate 11

The first conductive film 34 covers the surface 32a of the gate insulating film 32 that is formed in a region in which the channel region 31 is formed.

The first conductive film 34 is U-shaped. The first conductive film 34 has end portions 37 and 38. The end portions 37 and 38 are closer to the surface 11a of the semiconductor substrate than the bottom 26c of the second groove 26. The end portion 37 of the first conductive film 34 is disposed to face the side surface 28c of the first impurity diffusion layer 28 while the gate insulating film 32 is interposed between the end portion 37 and the side surface 28c. The end portion 38 of the first conductive film 34 is disposed to face the side surface 29c of the second impurity diffusion layer 29 while the gate insulating film 32 is interposed between the end portion 38 and the side surface 29c. The end portions 37 and 38 are positioned at opposite sides of the first conductive film 34 and are positioned in opposite sides with respect to the second conductive film 35.

The end portion 37 of the first conductive film 34 has an upper surface 37a, which is defined by etching process. The upper surface 37a is lower than the surface 11a of the semiconductor substrate 11 and higher than the upper surface 35a of the second conductive film 35. The upper surface 37a is higher than the top of the second conductive film 35. The upper surface 37a is higher than a first close portion of the second conductive film 35. The first close portion is closer to the upper surface 37a of the first conductive film 34 than the other portion of the second conductive film 35. The first close portion may be in contact with the first conductive film 34.

The end portion 38 of the first conductive film 34 has an upper surface 38a, which is defined by etching process. The upper surface 38a is lower than the surface 11a of the semiconductor substrate 11 and higher than the upper surface 35a of the second conductive film 35. The upper surface 38a is higher than the top of the second conductive film 35. The upper surface 38a is higher than a second close portion of the second conductive film 35. The second close portion is closer to the upper surface 38a of the first conductive film 34 than the other portion of the second conductive film 35. The second close portion may be in contact with the first conductive film 34.

The first conductive film 34 may be smaller in thickness than the second conductive film 35. The first conductive film 34 may be smaller in horizontal dimension than the second conductive film 35. Reduction of the thickness or horizontal dimension of those films will make it easy to ensure the flatness of the etched upper surface of those films. The flatness of the etched upper surface of those films will be affected by crystal grain boundaries of those films. The first conductive film 34 being thinner is capable of being etched at a more uniform rate, and the second conductive film 35 being thicker is capable of being etched at a less uniform rate. The respective levels of the upper surfaces 37a and 38a of the end portions 37 and 38 of the first conductive film 34 are more uniform than the level uniformity of the upper surface 35a of the second conductive film 35. In typical cases, the upper surfaces 37a and 38a of the end portions 37 and 38 of the first conductive film 34 are substantially the same in level.

Hereinafter, the “upper surface 37a of the end portion 37 of the first conductive film 34” will be referred to as “upper surface 37a of the first conductive film 34” and the “upper surface 38a of the end portion 38 of the first conductive film 34” will be referred to as “upper surface 38a of first conductive film 34.”

The second depth D₂ from the surface 28a of the first impurity diffusion layer 28 (the surface 11a of the semiconductor substrate 11) to the upper surface 37a of the first conductive film 34 is substantially equal to the third depth D₃ from the surface 29a of the second impurity diffusion layer 29 (the surface 11a of the semiconductor substrate 11) to the upper surface 38a of the first conductive film 34. The second depth D₂ and the third depth D₃ may be, but is not limited to, 35 nm.

As described above, making the second depth D₂ substantially equal to the third depth D₃ allows the end portions 37 and 38 of the first conductive film 34 to have a bilaterally symmetrical shape as shown in FIG. 2. The first conductive film 34 is a part of the gate electrode 33. Thus, the transistor 15 is free of off-set structure. This structure will provide no undesired affects to the characteristics of the transistor 15. The difference of characteristics among a plurality of transistors 15 can be suppressed.

The first conductive film 34A may have a predetermined work function. The first conductive film 34A may be made of a material that facilitates control of a threshold voltage. The first conductive film 34A may be a film with a small thickness and easily etched.

Specifically, the first conductive film 34 may be made of at least one of a polycrystalline silicon film which contains a dopant impurity (P-type or N-type), a titanium nitride film, a tantalum nitride film, a molybdenum nitride film, a cobalt silicide film, and a nickel silicide film. Also, the first conductive film 34 may be made of a stacked film of at least two films described above.

In some cases, when the titanium nitride film, whose work function is 4.75 eV, is used as the first conductive film 34, the first conductive film 34 may be formed, but is not limited to, with a thickness of 5 nm on the plane of the substrate.

The second conductive film 35 is formed on the surface 34a of the first conductive film 34. The second conductive film 35 is buried in a portion of the second groove 26 in which the first conductive film 34 is formed. The second conductive film 35 is low in resistivity than the first conductive film 34. The second conductive film 35 is provided for reducing resistance of the gate electrode 33.

The second conductive film 35 is greater in thickness than the first conductive film 34. Thereby, as shown in FIG. 2, in the second conductive film 35, pillar-shaped crystal grains 41 tends to be grown. A number of crystal grain boundaries 42 are present between the crystal grains 41, unlike the first conductive film 34. The crystal grain boundary 42 has a higher etching rate than the crystal grains 41. As shown in FIG. 2, the etched upper surface 35a of the second conductive film 35 which is formed by etching process is non-flat.

The upper surface 35a of the second conductive film 35 is lower than the upper surfaces 37a and 38a of the first conductive film 34. The upper surface 35a of the second conductive film 35 is closer to the bottom 26c of the second groove 26 than the upper surfaces 37a and 38a of the first conductive film 34.

The second conductive film 35 may be formed of one of a cobalt silicide film, a nickel silicide film, a tungsten film, a molybdenum film, a cobalt film, a nickel film, a copper film, and an aluminum film.

In some cases, when the tungsten film is used as the second conductive film 35, the second conductive film 35 may be formed, but is not limited to, with a thickness of 30 nm on the plane of the substrate.

The space 36 is surrounded by an inner wall of the first conductive film 34 and the upper surface 35a of the second conductive film 35. The space 36 is made by making the upper surface 35a of the second conductive film 35 lower than the upper surfaces 37a and 38a of the first conductive film 34.

The first insulating film 17 is buried in the space 36 to cover the upper surface 35a of the second conductive film 35.

The first insulating film 17 covering the upper surface 35a of the second conductive film 35 as described above can prevent the heavy-metal atoms contained in the second conductive film 35 from being diffused into the semiconductor substrate 11. The heavy-metal atoms adversely affect characteristics of the transistor 15.

A surface 17a of the first insulating film 17 is flat. The surface 17a of the first insulating film 17 may be substantially the same in level as the upper surfaces 37a and 38a of the first conductive film 34. For example, a silicon oxide film (SiO₂ film) may be used as the first insulating film 17.

The first insulating film 17 has a first side surface which faces to a side surface of the end portion 37. The first insulating film 17 has a second side surface which faces to a side surface of the end portion 38.

The example in which the surface 17a of the first insulating film 17 is substantially the same in level as the upper surfaces 37a and 38a of the first conductive film 34 is shown by way of example in FIG. 2. In some cases, the surface 17a of the first insulating film 17 may be closer to the bottom 26c of the second groove 26 than the upper surfaces 37a and 38a of the first conductive film 34. In this case, the upper surface 35a of the second conductive film 35 is entirely covered by the first insulating film 17.

The second insulating film 18 is disposed in the second groove 26 in which the gate electrode 35 and the first insulating film 17 are formed. The second insulating film 18 protrudes from the surface 11a of the semiconductor substrate 11. A bottom of the second insulating film 18 is in contact with the upper surfaces 37a and 38a of the first conductive film 34 and the surface 17a of the first insulating film 17. For example, a silicon oxide film (SiO₂ film) may be used as the second insulating film 18.

The interlayer insulating film 19 is disposed on the surface 12a of the third insulating film 12. The interlayer insulating film 19 covers the second insulating film 18. For example, a silicon oxide film (SiO₂ film) with a thickness of 100 nm may be used as the interlayer insulating film 19.

The first contact plug 21 penetrates the interlayer insulating film 19. A lower end of the first contact plug 21 is in contact with the first impurity diffusion layer 28.

The second contact plug 22 penetrates the interlayer insulating film 19. A lower end of the second contact plug 22 is in contact with the second impurity diffusion layer 29.

The third contact plug 23 penetrates the first insulating film 17, the second insulating film 18, and the interlayer insulating film 19. A lower end of the third contact plug 23 is in contact with the upper surface 35a of the second conductive film 35. Accordingly, the third contact plug 23 is electrically connected to the gate electrode 33.

The semiconductor device 10 including the elements as described above operates as follows. While drain current is applied to the first impurity diffusion layer 28 via the first contact plug 21 and source current is applied to the second impurity diffusion layer 29 via the second contact plug 22, an ON voltage is applied to the gate electrode 33 via the third contact plug 23. Thereby, the channel region 31 is formed and ON current flows into the transistor 15.

According to the semiconductor device of the first embodiment, the second depth D₂ from the surface 28a of the first impurity diffusion layer 28 (the surface 11a of the semiconductor substrate 11) to the upper surface 37a of the first conductive film 34 is substantially equal to the third depth D₃ from the surface 29a of the second impurity diffusion layer 29 (the surface 11a of the semiconductor substrate 11) to the upper surface 38a of the first conductive film 34. The depths of the first and second impurity diffusion layers 28 and 29 are greater than the second depth D₂ and the third depth D₃. Therefore, the end portions 37 and 38 of the first conductive film 34 which is the part of the gate electrode 33 have a bilaterally symmetrical shape (see FIG. 2). The end portions 37 and 38 of the first conductive film 34 are free of an offset structure with respect to the first and second impurity diffusion layers 28 and 29. This structure will provide no undesired affects to the characteristics of the transistor 15. The variation of the characteristics among different products of the transistor 15 can be suppressed.

The upper surface 35a of the second conductive film 35 is closer to the bottom 26c of the second groove 26 than the upper surfaces 37a and 38a of the end portions 37 and 38 of the first conductive film 34. The first insulating film 17 covers the upper surface 35a of the second conductive film 35. Accordingly, the heavy-metal atoms contained in the second conductive film 35 are suppressed from being diffused into the semiconductor substrate 11. The heavy-metal atoms adversely affect characteristics of the transistor 15. Accordingly, increase of junction leakage current of the transistor 15 can be suppressed.

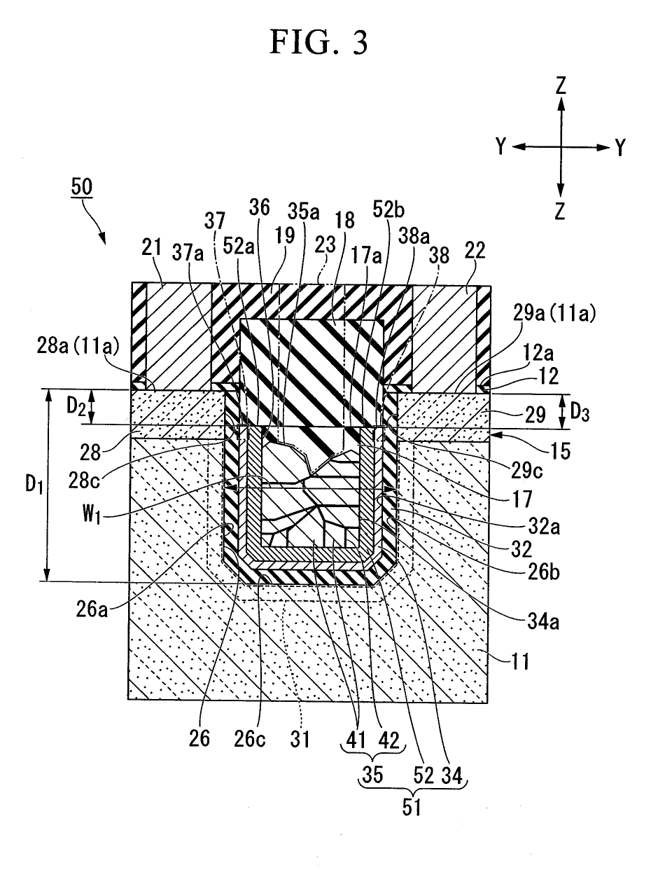

FIG. 3 is a fragmentary cross sectional view illustrating a semiconductor device according to a variant of the first embodiment of the present invention. In FIG. 3, the same elements as those of the semiconductor device 10 of the first embodiment illustrated in FIG. 2 are assigned the same reference numerals and a description thereof will be omitted.

Referring to FIG. 3, a semiconductor device 50 according to a variant of the first embodiment has the same configuration as the semiconductor device 10 except that the gate electrode 33 provided in the semiconductor device 10 of the first embodiment is replaced with a gate electrode 51.

The gate electrode 51 has the same configuration as the above-described gate electrode 33 except that a third conductive film 52 is provided between the first conductive film 34 and the second conductive film 35.

The third conductive film 52 is U-shaped. One upper surface 52a of the third conductive film 52 is substantially the same in level as the upper surface 37a of the first conductive film 34. The other upper surface 52b of the third conductive film 52 is substantially the same in level as the upper surface 38a of the first conductive film 34. In some cases, the upper surface 52a of the third conductive film 52 may be substantially the same in level as a first contact portion of the second conductive film 35. The first contact portion of the second conductive film 35 is adjacent to the upper surface 52a of the third conductive film 52 and contacts the third conductive film 52. Also, the upper surface 52b of the third conductive film 52 may be substantially the same in level as a second contact portion of the second conductive film 35. The second contact portion of the second conductive film 35 is adjacent to the upper surface 52b of the third conductive film 52 and contacts the third conductive film 52.

The third conductive film 52 is provided for preventing reaction between the first conductive film 34 and the second conductive film 35, which is effective when the reaction between the first conductive film 34 and the second conductive film 35 is desired to be prevented.

The third conductive film 52 may be formed of one of a titanium nitride film, a tantalum nitride film, a molybdenum nitride film, and a tungsten nitride film.

Specifically, when, for example, an N-type polycrystalline silicon film is used as the first conductive film 34 and a tungsten film is used as the second conductive film 35, the titanium nitride film (e.g., having thickness of 2 nm) is provided as the third conductive film 52 between the N-type polycrystalline silicon film and the tungsten film, thereby preventing reaction between the N-type polycrystalline silicon film and the tungsten film.

The semiconductor device 50 configured as described above according to a variant of the first embodiment can have the same effects as the semiconductor device 10 of the first embodiment. The transistor 15 can have the desired characteristics. The difference of the characteristics among different products of the transistor 15 can be suppressed.

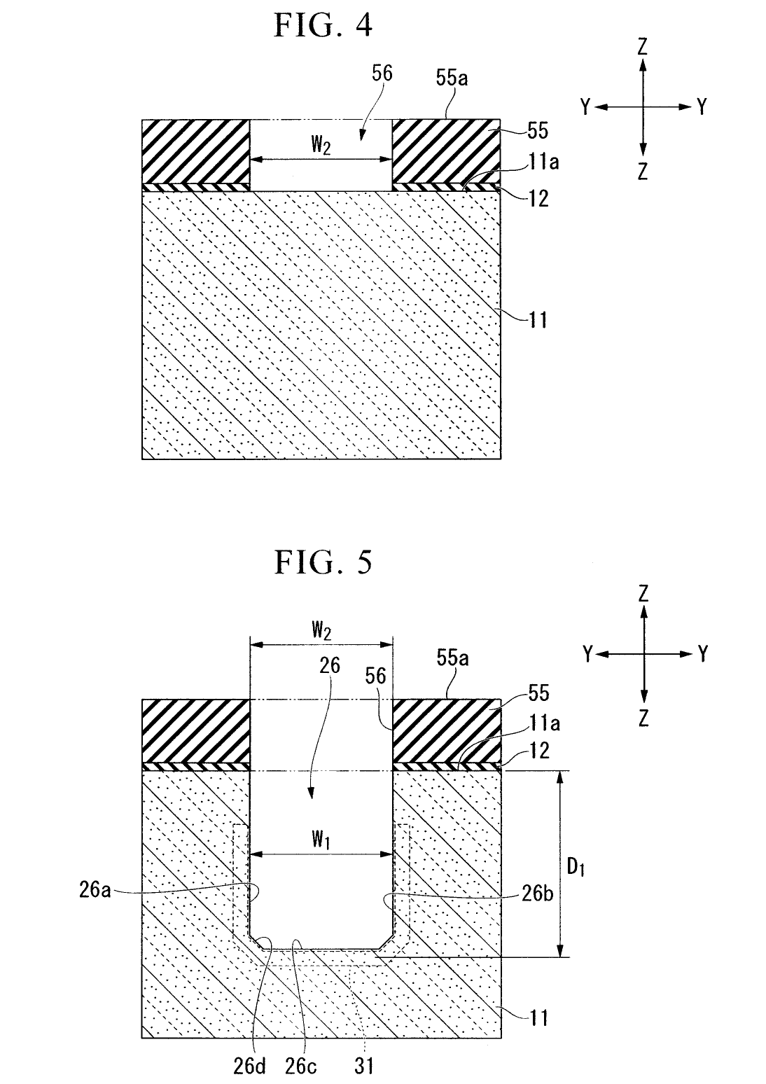

FIGS. 4 to 16 are fragmentary cross-sectional views illustrating a transistor in a step involved in a method of forming the semiconductor device according to the first embodiment of the present invention. FIGS. 4 to 16 are the fragmentary cross-sectional views taken along an A-A line. Namely, FIGS. 4 to 16 are the fragmentary cross-sectional views corresponding to the fragmentary cross sectional view of FIG. 2.

In FIGS. 4 to 16, the same elements as those of the semiconductor device 10 are assigned the same reference numerals. In the cross sectional views of the structure shown in FIGS. 4 to 16, it is difficult to show the isolation region 13 and the first groove 25 shown in FIG. 1. Therefore, these will be omitted in FIGS. 4 to 16.

A method of fabricating the semiconductor device 10 of the first embodiment will be described with reference to FIGS. 4 to 16.

In a process shown in FIG. 4, for example, a P-type silicon substrate which includes boron as a P-type impurity may be prepared as the semiconductor substrate 11. A concentration of boron in the semiconductor substrate 11 may be 1.0×10¹⁷ atoms/cm³. Then, the first groove 25 (not shown) is formed in the semiconductor substrate 11. An insulating film (e.g., a silicon oxide film (SiO₂ film)) is buried into the first groove 25 to form the isolation region 13 (not shown).

The third insulating film 12 and the fourth insulating film 55 are then sequentially stacked on the surface 11a of the semiconductor substrate 11. Specifically, for example, a silicon oxide film (SiO₂ film) with a thickness of 10 nm may be formed as the third insulating film 12. A silicon nitride film (SiN film) with a thickness of 100 nm may be formed as the fourth insulating film 55.

A patterned photoresist (not shown) is formed on the fourth insulating film 55. The third and fourth insulating films 12 and 55 are etched by anisotropic etching process (e.g., dry etching process) using the photoresist as a mask to form a through hole 56. The surface 11a of the semiconductor substrate 11 is shown through the through hole 56. The photoresist is removed after the through hole 56 is formed. A width W₂ of the through hole 56 may be, but is not limited to, 60 nm.

In a process shown in FIG. 5, the semiconductor substrate 11 located below the through hole 56 is etched by anisotropic etching process (e.g., dry etching process) using the fourth insulating film 55 with the through hole 56 as a mask to form the second groove 26. The second groove 26 has the inner surface including first and second side surfaces 26a and 26b, which are vertical wall surfaces, and the bottom 26c.

In this case, when another through hole 56 in the fourth insulating film 55 is formed on the isolation region 13 (not shown), another second groove 26 is formed in the isolation region 13 (not shown) in the corresponding portion.

A depth of the second groove 26 formed in the isolation region 13 (not shown) may be the same as or different from that of the second groove 26 formed in the semiconductor substrate 11.

When the depth of the second groove 26 formed in the isolation region 13 (not shown) is different from the depth D₁ of the second groove 26 formed in the semiconductor substrate 11, the second groove 26 is formed as follows. Etching gas is prepared to make an etching rate of the semiconductor substrate 11 different from that of an insulating film (silicon oxide film (SiO₂ film)) constituting the isolation region 13.

The depth D₁ of the second groove 26 may be, but is not limited to, 150 nm. Further, the width W₁ of the second groove 26 may be, but is not limited to, 60 nm. The width W₁ of the second groove 26 may be determined according to desired characteristics of the transistor 15. The depth D₁ and the width W₁ of the second groove 26 are not limited to such values.

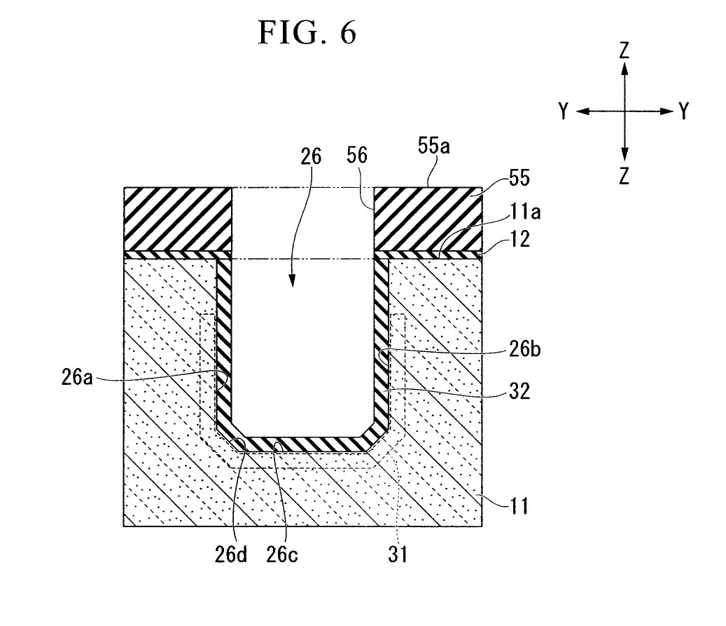

In a process shown in FIG. 6, the gate insulating film 32 is formed to cover the side surfaces 26a and 26b and the bottom 26c (including corner portions 26d) of the second groove 26. Thereby, the gate insulating film 32 faces the channel region 31.

For example, a single layer silicon oxide film (SiO₂ film) formed by thermal oxidation may be used as the gate insulating film 32. In some cases, when the single layer silicon oxide film (SiO₂ film) is used as the gate insulating film 32, a thickness of the gate insulating film 32 may be, but is not limited to, 6 nm.

When the gate insulating film 32 is formed by thermal oxidation, the silicon oxide film formed on the bottom 26c including the corner portions 26d of the second groove 26 is smaller in thickness than the silicon oxide film formed on the side surfaces 26a and 26b of the second groove 26.

In order to improve a gate withstand voltage of the gate insulating film 32, the gate insulating film 32 may be formed by stacking the single layer silicon oxide film (SiO₂ film) formed by thermal oxidation and an insulating film (e.g., a silicon oxide film (SiO₂ film) or a silicon nitride film (SiN film)).

Further, the insulating film formed on the silicon oxide film (SiO₂ film) formed by thermal oxidation may be formed, for example, by a chemical vapor deposition (CVD) method.

Further, when a thickness of the oxide film as the gate insulating film 32 is not desired to be increased, a film with high dielectric constant (not shown) may be formed, by a CVD method, on the silicon oxide film (SiO₂ film) formed by thermal oxidation.

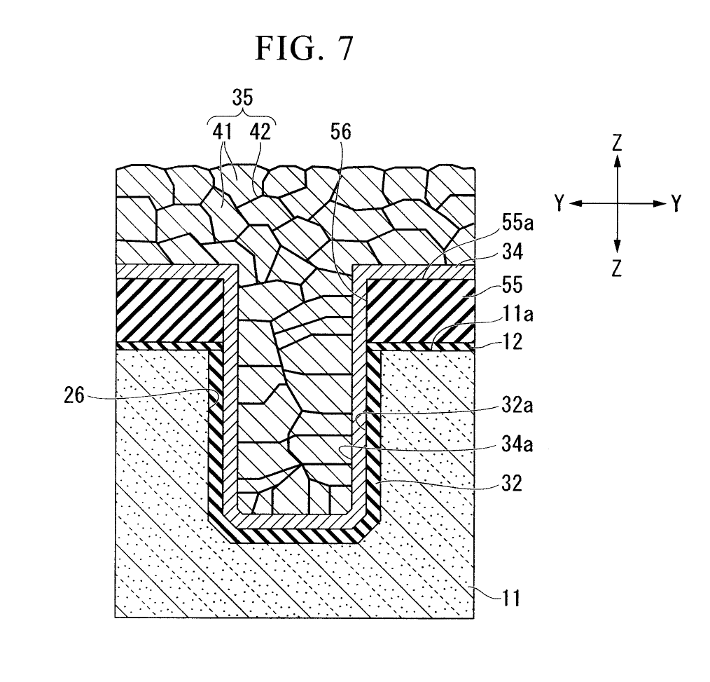

In a process shown in FIG. 7, the first conductive film 34 is formed to cover the surface 32a of the gate insulating film 32, the side surface of the through hole 56, and the surface 55a of the fourth insulating film 55.

The first conductive film 34 shown in FIG. 7 is not yet etched. When the first conductive film 34 is etched, the first conductive film 34 with the end portions 37 and 38 shown in FIG. 2 is obtained. The first conductive film 34 may be formed by, for example, the CVD method.

The first conductive film 34 determines a threshold voltage. The first conductive film 34 can prevents the heavy-metal atoms contained in the second conductive film 35 from being diffused into the semiconductor substrate 11. The heavy-metal atoms adversely affect characteristics of the transistor 15.

The first conductive film 34A may be made of a material that facilitates control of a threshold voltage. The first conductive film 34A may be a film with a small thickness and easily etched.

Specifically, the first conductive film 34 may be made of at least one of a polycrystalline silicon film which contain dopant impurities, a titanium nitride film, a tantalum nitride film, a molybdenum nitride film, a cobalt silicide film, and a nickel silicide film. Also, the first conductive film 34 may be made of a stacked film of at least two films described above.

In the first conductive film forming process, the first conductive film 34 is formed with smaller thickness than the second conductive film 35.

Such a smaller thickness of the first conductive film 34 suppresses the etching rate of the first conductive film 34 from being non-uniform when the first conductive film 34 is etched.

The first conductive film 34 is etched in a process shown in FIG. 13, which will be described below. The first conductive film 34 has etched surfaces, for example, the upper surfaces 37a and 38a. The etched upper surfaces 37a and 38a are flat. The etching process for etching the first conductive film 34 can be easily controlled in its etching depth which is defined in a depth direction Z-Z of the second groove 26.

Thus, products of the transistor 15 are almost uniform or less different in the etching depth in etching the first conductive film 34. There can be suppressed a difference between a depth from the surface 11a of the semiconductor substrate 11 to the upper surface 37a of the first conductive film 34 and a depth from the surface 11a of the semiconductor substrate 11 to the upper surface 38a of the first conductive film 34. Also, differences of the characteristics among the products of the transistor 15 can be suppressed.

In some cases, when the titanium nitride film is formed as the first conductive film 34, the thickness of the first conductive film 34 formed on the surface 55a of the fourth insulating film 55 may be, but is not limited to, 5 nm.

The second conductive film 35 covering the surface 34a of the first conductive film 34 is then formed to be buried in the second groove 26 and the through hole 56.

In this case, the second conductive film 35 is also formed on the first conductive film 34 formed on the surface 55a of the fourth insulating film 55. The second conductive film 35 may be formed, for example, by a CVD method.

The second conductive film 35 shown in FIG. 7 is not yet etched. When the second conductive film 35 is etched, the second conductive film 35 with the non-flat upper surface 35a shown in FIG. 2 is formed.

The second conductive film 35 is smaller in resistance than the first conductive film 34. The second conductive film 35 reduces resistance of the gate electrode 33. Since the second conductive film 35 needs to be buried in the second groove 26 and the through hole 56, the second conductive film 35 is formed with a greater thickness than the first conductive film 34.

As shown in FIG. 7, the second formed conductive film 35 includes a plurality of crystal grains 41 having different shapes and crystal grain boundaries 42 formed among the plurality of crystal grains 41.

In the second conductive film 35 configured as described above, the etching rate of the crystal grain boundaries 42 formed among the crystal grains 41 is higher than that of the crystal grains 41, which makes the etching rate non-uniform.

The second conductive film 35 shown in FIG. 7 is etched in a process shown in FIG. 9, which will be described below. The upper surface 35a of the second conductive film 35, which is the etched surface, is non-flat due to the non-uniform etching rate.

The second conductive film 35 may be formed of one of a cobalt silicide film, a nickel silicide film, a tungsten film, a molybdenum film, a cobalt film, a nickel film, a copper film, and an aluminum film.

In some cases, when the second groove 26 has a width of 60 nm and the titanium nitride film with a thickness of 6 nm is used as the first conductive film 34, a tungsten film may be formed as the second conductive film 35. The thickness of the tungsten film on the surface of the substrate may be, but is not limited to, 30 nm.

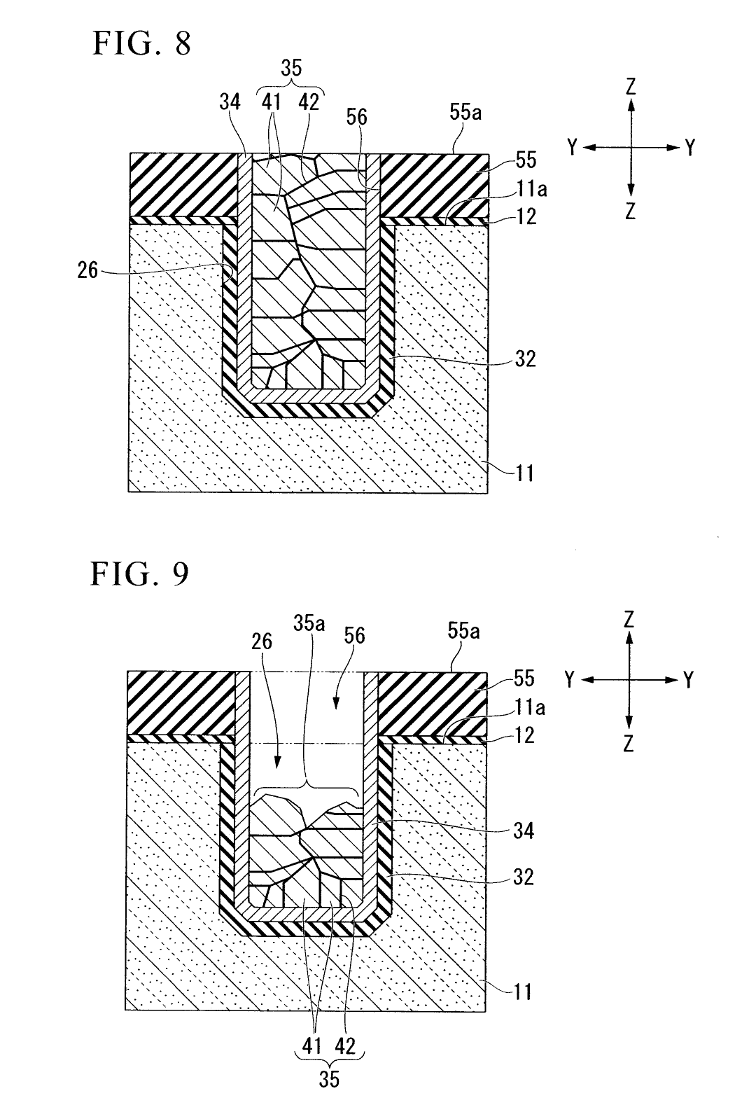

In a process shown in FIG. 8, a portion of the first conductive film 34 and a portion of the second conductive film 35 shown in FIG. 7 on the surface 55a of the fourth insulating film 55 are removed by a chemical mechanical polishing (CMP) method to planarize the surface of the substrate 11 shown in FIG. 8. During removing the portion of the first conductive film 34 and the portion of the second conductive film 35, the fourth insulating film 55 (silicon nitride film (SiN film)) is used as a polishing stopper film.

In a process shown in FIG. 9, the second conductive film 35 is selectively etched by an anisotropic etching method (e.g., dry etching method) using an etching condition of a high selectivity ratio to the first conductive film 34. The second conductive film 35 included the removed upper portion which was to be removed by the anisotropic etching method. The removed upper portion was present both in the through hole 56 and in an upper portion of the second groove 26 shown in FIG. 8. The upper surface 35a of the second conductive film 35 as etched by the etching process is non-flat as shown in FIG. 2.

In the second conductive film etching process, an average depth from the surface 11a of the semiconductor substrate 11 to the upper surface 35a of the second conductive film 35 may be, but is not limited to, 60 nm.

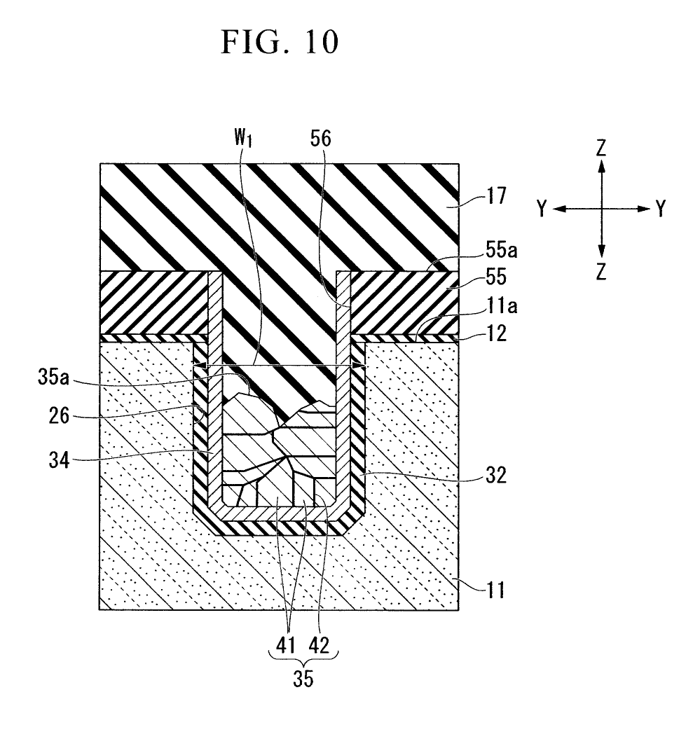

In a process shown in FIG. 10, the first insulating film 17 is formed to be buried in the second groove 26 and the through hole 56. In the second groove 26, the first and second conductive films 34 and 35 are formed. In the through hole 56, the first conductive film 34 is formed. The thickness of the first insulating film 17 may be determined to be enough to form a flat surface of the first insulating film 17 shown in FIG. 10.

The first insulating film 17 may be formed, but is not limited to, by a CVD method. For example, a silicon oxide film (SiO₂ film) may be used as the first insulating film 17. In some cases, when the second groove 26 has the width W₁ of 60 nm and the silicon oxide film (SiO₂ film) is used as the first insulating film 17, the first insulating film 17 on the surface 55a of the fourth insulating film 55 may be formed, but is not limited to, with a thickness of 50 nm.

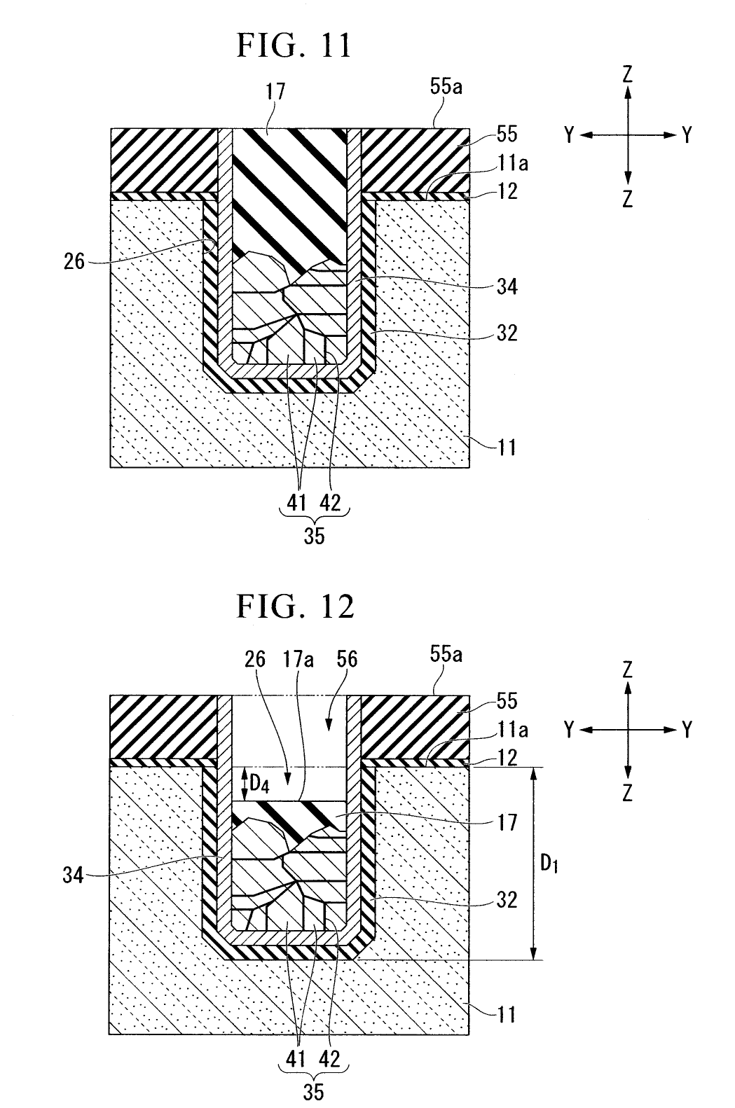

In a process shown in FIG. 11, the first insulating film 17 has a portion located above the surface 55a of the fourth insulating film 55 shown in FIG. 10. The portion of the first insulating film 17 is then removed by a CMP method to planarize the surface of the first insulating film 17 and the surface 55a of the fourth insulating film 55 shown in FIG. 11. During removing the portion of the first insulating film 17, the fourth insulating film 55 (silicon nitride film (SiN film)) is used as a polishing stopper film.

In a process shown in FIG. 12, an etch-back process of the first insulating film 17 shown in FIG. 11 is performed by an anisotropic etching method (e.g., a dry etching method). The first insulating film 17 has the flat surface 17a etched back shown in FIG. 2. The flat surface 17a is lower than the surface 11a of the semiconductor substrate 11.

The first etched insulating film 17 after the etch-back process does not cover a portion of the first conductive film 34. The portion of the first conductive film 34 will be etched in a process shown in FIG. 13 (a first conductive film etching process), which will be described below.

Accordingly, in the process shown in FIG. 13, the first insulating film 17 with the flat surface 17a can be used as a mask for etching the first conductive film 34, thereby accurately etching the first conductive film 34.

In some cases, when the depth D₁ of the second groove 26 is 150 nm, a depth D₄ from the surface 11a of the silicon substrate 11 to the surface 17a of the first insulating film 17 (the surface of the first etched insulating film 17) may be, but is not limited to, 30 nm.

The silicon oxide film (SiO₂ film) has a uniform film quality. When the silicon oxide film (SiO₂ film) is used as the first insulating film 17, the depth D₄ can be easily controlled and the flat surface 17a of the first etched insulating film 17 can be obtained.

In the process shown in FIG. 13, there is etched the portion, which is not covered by the first insulating film 17, of the first conductive film 34 formed on the side surfaces 26a and 26b of the second groove 26, specifically, the first conductive film 34 protruding from the surface 17a of the first insulating film 17. The etching process is performed using the first insulating film 17 with the flat surface 17a as a mask. The gate insulating film 32 is partially shown after the etching process. The first conductive film 34 has the end portions 37 and 38 with the upper surfaces 37a and 38a. The upper surfaces 37a and 38a is higher than the upper surface 35a of the second conductive film 35.

The first conductive film 34 extends along the side surfaces 26a and 26b of the second groove 26 in the depth direction of the second groove 26 (direction Z-Z).

Thus, the gate electrode 33 shown in FIG. 2 is formed in the second groove 26. In the first conductive film etching process, the end portion 37 of the first conductive film 34 is formed in a position facing the first impurity diffusion layer 28 shown in FIG. 2. Also, the end portion 38 of the first conductive film 34 is formed in a position so that the end portion 38 faces the second impurity diffusion layer 29 shown in FIG. 2.

Since the thickness of the first conductive film 34 is small as described above, the variation of the etching rate in etching the first conductive film 34 is small. Accordingly, the upper surfaces 37a and 38a of the first conductive film 34, which are the etched surfaces, are substantially flat surfaces and disposed on the same level.

Accordingly, among the plurality of transistors 15, the second depth D₂ from the surface 11a of the semiconductor substrate 11 to the upper surface 37a of the first conductive film 34 can be equal to the third depth D₃ from the surface 11a of the semiconductor substrate 11 to the upper surface 38a of the first conductive film 34. The difference of characteristics among the plurality of transistors 15 can be suppressed.

The first conductive film 34 is selectively etched while the second conductive film 35 is covered with the first insulating film 17. The second conductive film 35 is not etched by selectively etching the first conductive film 34. Therefore, the heavy-metal atoms contained in the second conductive film 35 are not diffused into the semiconductor substrate 11. The heavy-metal atoms adversely affect characteristics of the transistor 15. Accordingly, no diffusion or reduced diffusion will permit the plurality of transistors 15 to have the desired characteristics.

The isotropic etching process or the anisotropic etching process may be used to etch the first conductive film 34. For example, a wet etching process or a dry etching process may be used as isotropic etching process. Further, for example, the dry etching process may be used as anisotropic etching process.

In some cases, a titanium nitride film with a thickness of 5 nm may be used as the first conductive film 34. The first conductive film 34 is wet-etched until twice the thickness of the first conductive film 34 is etched (i.e., when an over-etching amount is 100%). In this case, the upper surfaces 37a and 38a of the first conductive film 34 are about 5 nm lower than the surface 17a of the first insulating film 17.

In this case, the second depth D₂ from the surface 11a of the semiconductor substrate 11 to the upper surface 37a of the first conductive film 34 and the third depth D₃ from the surface 11a of the semiconductor substrate 11 to the upper surface 38a of the first conductive film 34 are 35 nm.

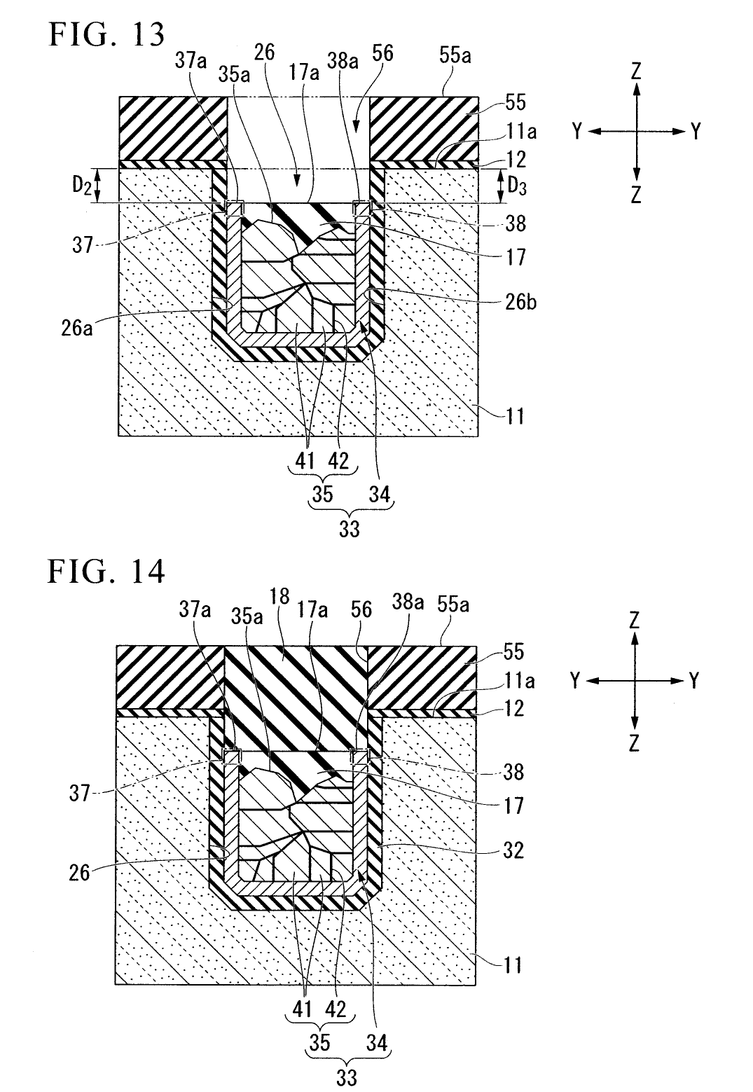

In a process shown in FIG. 14, the second insulating film 18 is formed to be buried in the second groove 26, in which the first insulating film 17 and the gate electrode 33 are formed, and the through hole 56.

For example, a silicon oxide film (SiO₂ film) may be used as the second insulating film 18. The second insulating film 18 may be formed as follows. A silicon oxide film (SiO₂ film) is formed at the side of the surface of the structure shown in FIG. 13. An extra silicon oxide film (SiO₂ film) formed on the surface 55a of the fifth insulating film is then removed using CMP.

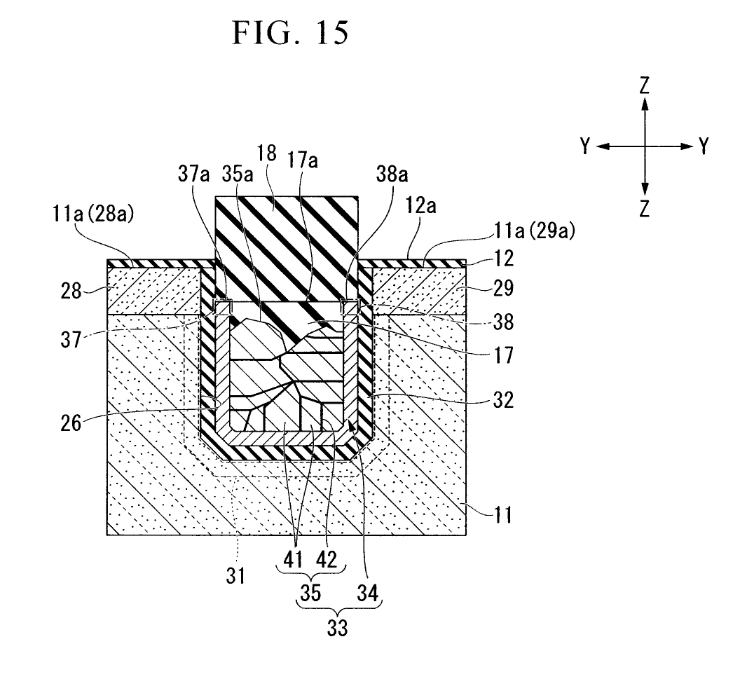

In a process shown in FIG. 15, the fourth insulating film 55 shown in FIG. 14 is removed. Then, an N-type impurity is ion-implanted into the surface 11a of the semiconductor substrate 11 to form the first and second impurity diffusion layers 28 and 29. In some cases, arsenic is ion-implanted into the surface 11a of the semiconductor substrate 11 with an implantation amount of 5.0×10¹³ atoms/cm³ and energy of 25K eV. The semiconductor substrate 11 is then annealed at 900° C. for 30 seconds for implantation damage recovery, to form the first and second impurity diffusion layers 28 and 29. In this case, the first and second impurity diffusion layers 28 and 29 may be formed, for example, with a depth of 45 nm from the surface 11a of the semiconductor substrate 11.

Thus, the transistor 15 including the first and second impurity diffusion layers 28 and 29, the channel region 31, the gate insulating film 32, and the gate electrode 33 is formed.

While only one transistor 15 is shown in FIG. 15, in fact, a plurality of transistors 15 is formed in the semiconductor substrate 11.

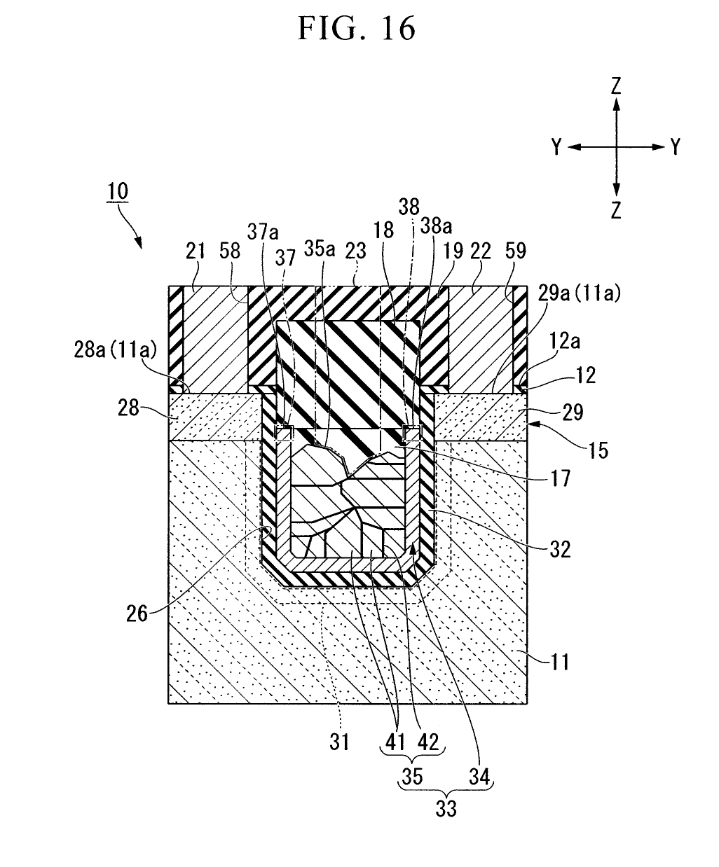

In a process shown in FIG. 16, the interlayer insulating film 19 is formed on the surface 12a of the third insulating film 12 to cover the second insulating film 18. In some cases, a silicon oxide film (SiO₂ film) with a thickness of 100 nm may be formed on the surface of the structure shown in FIG. 15 to form the interlayer insulating film 19.

Then, the patterned photoresist (not shown) is formed on the interlayer insulating film 19. The interlayer insulating film 19 is etched using the photoresist as a mask to form the opening 58 and the opening 59 by the same etching process. The surface 28a of the first impurity diffusion layer 28 is shown through the opening 58. The surface 29a of the second impurity diffusion layer 29 is shown through the opening 59. The photoresist is then removed.

Then, the patterned photoresist (not shown) is formed on the interlayer insulating film 19. The first insulating film 17, the second insulating film 18 and the interlayer insulating film 19 are etched using the photoresist as a mask to form the opening (not shown). The third contact plug 23 will be disposed in the opening.

The openings 58 and 59 and the opening (not shown) for the third contact plug 23 are filled with a conductive film to form the first to third contact plugs 21 to 23 in the same processes.

A wiring, an interlayer insulating film, a contact plug, and the like (all not shown), which are connected to any one of the first to third contact plugs 21 to 23, may be formed on the structure shown in FIG. 16.

According to the method of fabricating the semiconductor device of the first embodiment, the first conductive film 34 is formed to cover the surface 32a of the gate insulating film 32. The second conductive film 35 with a greater thickness than the first conductive film 34 is formed on the surface 34a of the first conductive film 34 to be buried in the second groove 26. The second conductive film 35 is selectively etched to remove a portion of the second conductive film 35 formed in the second groove 26. The first insulating film 17 is then formed to cover the upper surface 35a of the second conductive film 35. The heavy-metal atoms contained in the second conductive film 35 do not reach the gate insulating film 32 when the first conductive film 34 is etched. The heavy-metal atoms adversely affect characteristics of the transistor 15 when diffused into the semiconductor substrate 11. Since the increase of junction leakage current can be suppressed, the transistor 15 having stable characteristics can be formed.

The first conductive film 34 that is formed on the side surfaces 26a and 26b of the second groove 26 protrudes from the first insulating film 17. The first conductive film 34 with a smaller thickness than the second conductive film 35 is selectively etched. The first conductive film 34 is higher in the uniformity of etching rate than the second conductive film 35.

Accordingly, the difference of positions of the upper surfaces 37a and 38a of the first conductive film 34 in the depth direction of the second groove 26 can be suppressed. The difference of characteristics among a plurality of transistors 15 can be suppressed.

### Second Embodiment

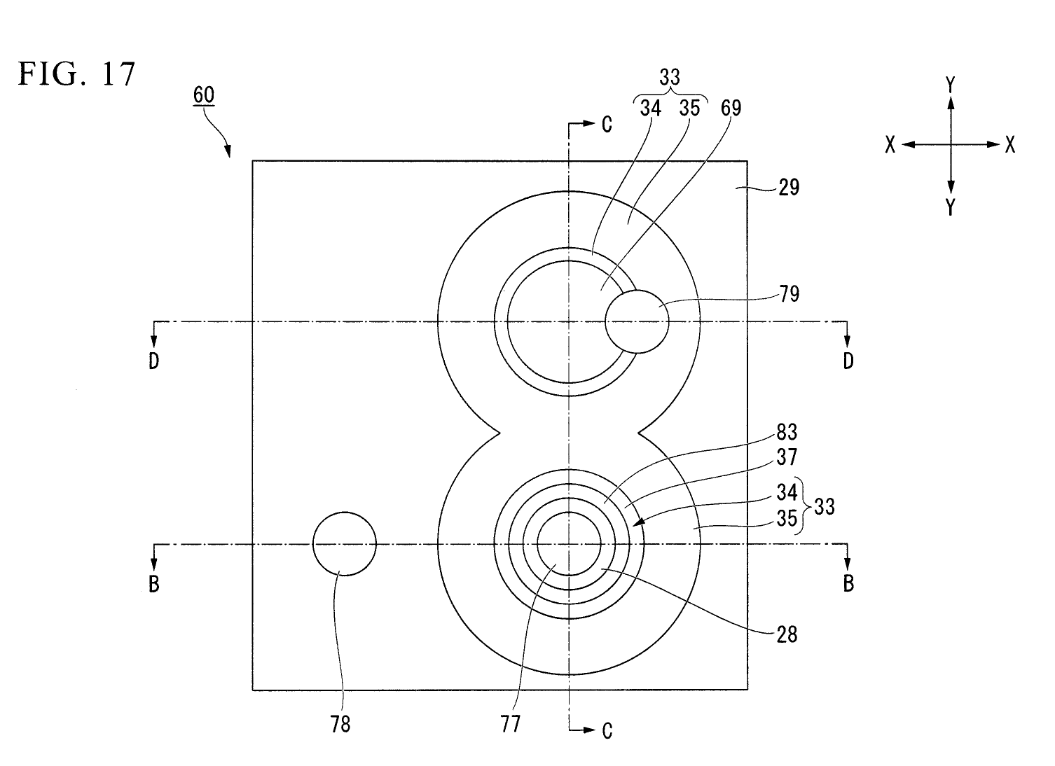

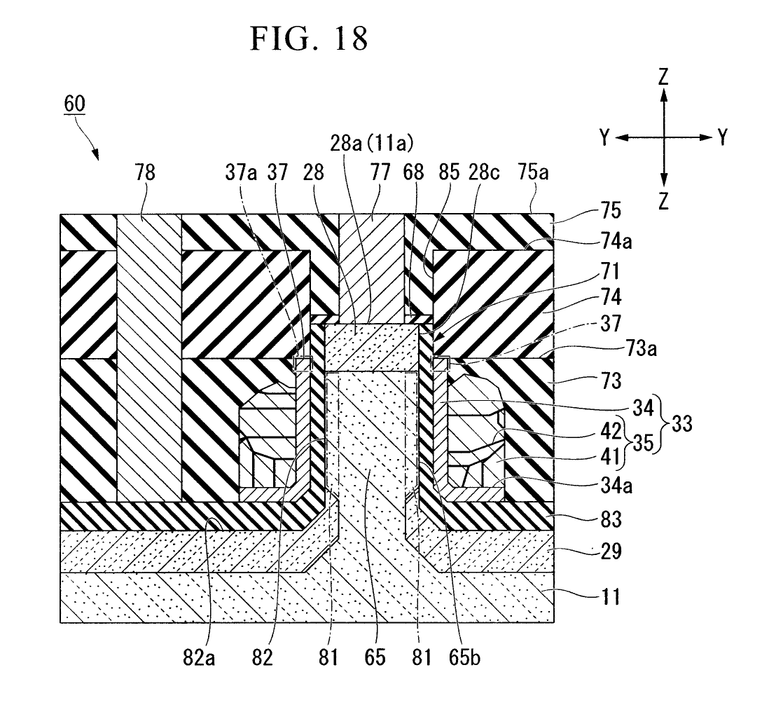

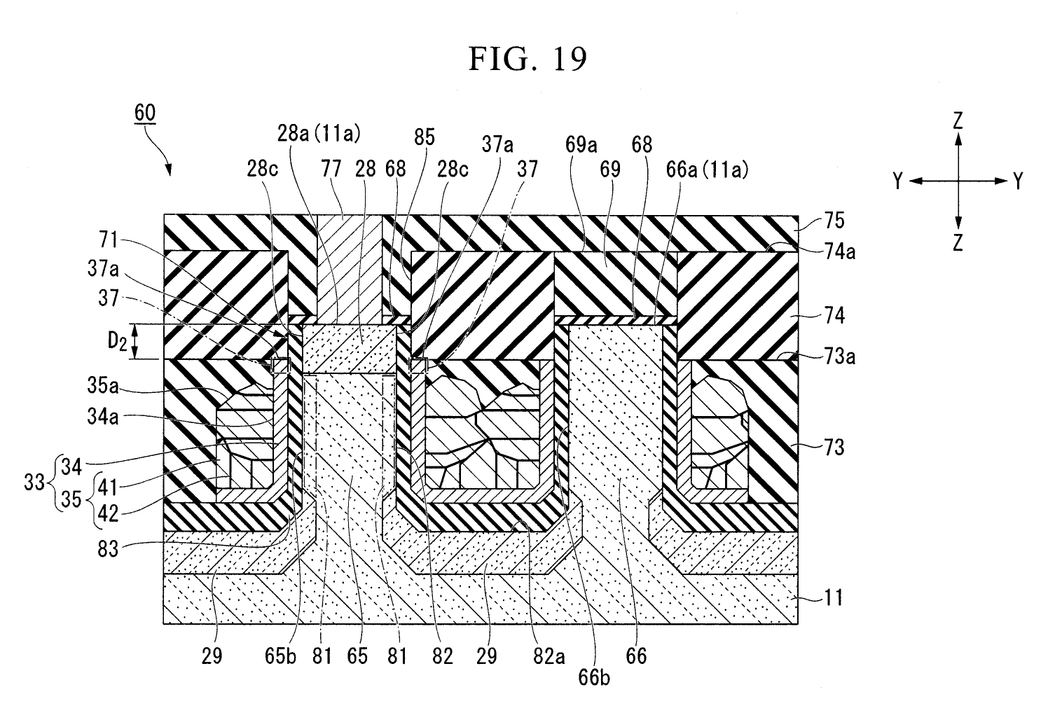

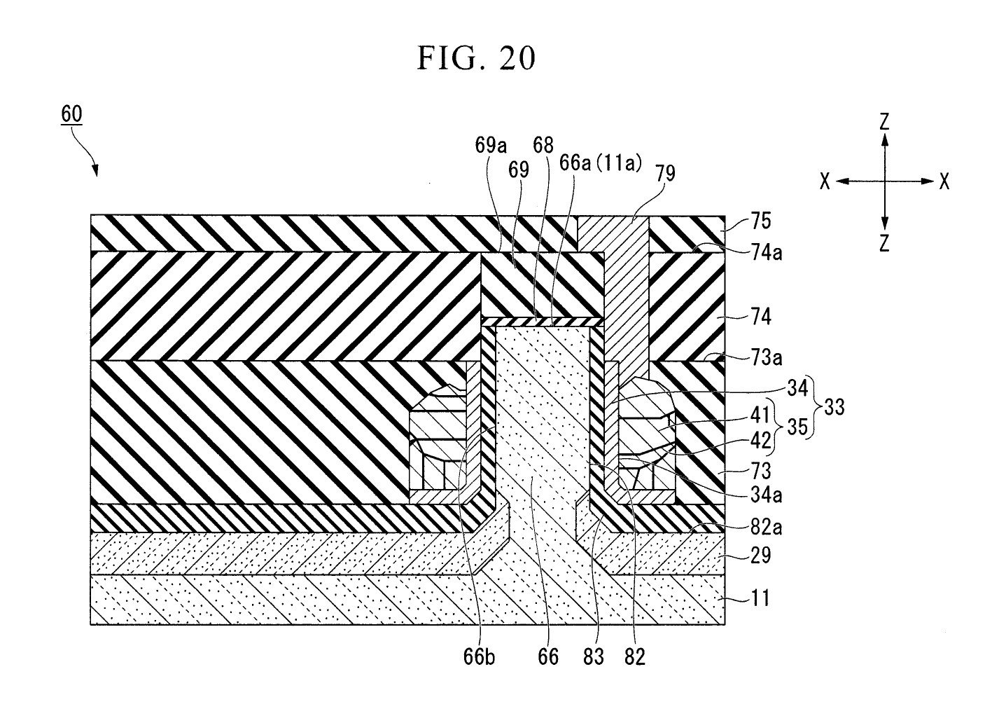

FIG. 17 is a fragmentary cross sectional elevation view illustrating a semiconductor device according to a second embodiment of the present invention. FIG. 18 is a fragmentary cross sectional elevation view taken along line B-B of the semiconductor device shown in FIG. 17. FIG. 19 is a fragmentary cross sectional elevation view taken along line C-C of the semiconductor device shown in FIG. 17. FIG. 20 is a fragmentary cross sectional elevation view taken along line D-D of the semiconductor device shown in FIG. 17.

In FIGS. 17 to 20, the same components as those of the semiconductor device 10 of the first embodiment are assigned the same reference numerals. Only one vertical transistor 71 is shown in FIGS. 18 and 19, but in fact, a plurality of vertical transistors 71 are formed in the semiconductor substrate 11.

In FIGS. 17 to 20, a direction Z-Z is a depth direction of grooves 82, a direction X-X is a direction orthogonal to the direction Z-Z, and a direction Y-Y is a direction orthogonal to the direction X-X and to the direction Z-Z.

Referring to FIGS. 17 to 20, a semiconductor device 60 of the second embodiment includes a semiconductor substrate 11, a plurality of pillars 65 and 66 that are pillar-shaped protrusions, a first insulating film 68, a second insulating film 69, a vertical transistor 71, a third insulating film 73, a fourth insulating film 74, a fifth insulating film 75, a first contact plug 77, a second contact plug 78, and a third contact plug 79.

The semiconductor substrate 11 has the grooves 82. The grooves 82 are formed by partially etching a surface 11a (main surface) of the semiconductor substrate 11. The grooves 82 have an inner surface including a vertical wall surface. A depth of the grooves 82 from the surface 11a of the semiconductor substrate 11 may be, but is not limited to, 120 nm.

The pillars 65 and 66 are protrusions that are formed by forming the grooves 82 in the semiconductor substrate 11, wherein the pillars 65 and 66 are defined by the grooves 82. The pillars 65 and 66 have side surfaces 65b and 66b (sidewall surfaces of the pillars 65 and 66) corresponding to the vertical wall surface of the grooves 82.

Although one of pillars 65 and one of pillars 66 are shown in FIGS. 17 and 19, the pillars 65 and the pillars 66 are disposed at predetermined small intervals.

In the case that a semiconductor device 60 has a 6F² cell structure of DRAM, a plurality of pillars 65 and a plurality of pillars 66 are disposed for the 6F² cell structure.

The first insulating film 68 is provided on an upper surface 66a of the pillar 66 and a surface 28a of the first impurity diffusion layer 28 located in the vicinity of the first contact plug 77. For example, a silicon oxide film (SiO₂ film) with a thickness of 10 nm may be used as the first insulating film 68.

The second insulating film 69 is provided on the first insulating film 68. The second insulating film 69 is a mask when the pillars 65 and 66 are formed. For example, a silicon nitride film (SiN film) with a thickness of 100 nm may be used as the second insulating film 69.

The vertical transistor 71 is a vertical metal oxide semiconductor (MOS) transistor. The vertical transistor 71 includes the pillar 66, the first impurity diffusion layer 28, a second impurity diffusion layer 29 (the other impurity diffusion layer), a channel region 81, a gate insulating film 83, and a gate electrode 33.

Descriptions will be omitted of materials and thicknesses of the same components as those of the transistor 15 described in the first embodiment, among components of the vertical transistor 71.

The first impurity diffusion layer 28 is located in a surface region of the pillar 65. The first impurity diffusion layer 28 is in the vicinity of the surface 11a of the semiconductor substrate 11.

The second impurity diffusion layer 29 is located in the vicinity of a bottom 82a of the groove 82 in the semiconductor substrate 11. One of the first and second impurity diffusion layers 28 and 29 functions as a source region, and the other functions as drain region.

The channel region 81 is formed in the semiconductor substrate 11 when the vertical transistor 71 is turned ON. The channel region 81 is formed in a portion of the pillar 65, which is located between the first impurity diffusion layer 28 and the second impurity diffusion layer 29.

The gate insulating film 83 is provided to cover the side surface 28c of the first impurity diffusion layer 28, the bottom 82a of the groove 82, and the side surfaces 65b and 66b of the pillars 65 and 66.

A portion of the gate insulating film 83 formed on the bottom 82a of the groove 82 is greater in thickness than the other portions. For example, a silicon oxide film (SiO₂ film) may be used as the gate insulating film 83.

The gate electrode 33 may include a first conductive film 34 and a second conductive film 35. The gate electrode 33 is common to the plurality of pillars 65 and 66.

The first conductive film 34 is provided for controlling a threshold voltage. The first conductive film 34 functions as a barrier film. The first conductive film 34 is provided on the side surfaces 65b and 66b of the pillars 65 and 66 and the bottom 82a of the groove 82. The first conductive film 34 extends along the first alignment of the plurality of pillars 65 and along the second alignment of the plurality of pillars 66, wherein the first conductive film 34 is interposed between the first and second alignments. The gate insulating film 83 extends along the first and second alignments of the plurality of pillars 65 and the plurality of pillars 66 and along the first conductive film 34. The gate insulating film 83 is interposed between the first conductive film 34 and the plurality of pillars 65 and between the first conductive film 34 and the plurality of pillars 66.

Accordingly, the first conductive film 34 may be used as a common conductive film to the plurality of pillars 65 and the plurality of pillars 66.

The first conductive film 34 has a ring-shaped end portion 37 that faces the first impurity diffusion layer 28 while the gate insulating film 83 is interposed between the ring-shaped end portion and the first impurity diffusion layer 28. A second depth D₂ is defined to be a distance from the surface 11a of the semiconductor substrate 11 to an upper surface 37a of the end portion 37 of the first conductive film 34. The second depth D₂ may be, but is not limited to, 35 nm.

The second conductive film 35 is provided on the surface 34a of the first conductive film 34. The second conductive film 35 extends along the first alignment of the plurality of pillars 65 and along the second alignment of the plurality of pillars 66, wherein the second conductive film 35 is interposed between the first and second alignments. An upper surface 35a of the second conductive film 35 is lower in level than the end portion 37 of the first conductive film 34 (at the side of the bottom 82a of the groove 82). The second conductive film 35 is a conductive film common to the pillars 65 and 66. The first and second conductive films 34 and 35 forms the gat electrode 33. The second conductive film 35 reduces resistance of the gate electrode 33.

In some cases, when an N-type polycrystalline silicon film is used as the first conductive film 34 and a tungsten film is used as the second conductive film 35, a titanium nitride film (e.g., having a thickness of 2 nm) may be provided as a third conductive film 52 (not shown) between the N-type polycrystalline silicon film and the tungsten film.

Accordingly, reaction between the N-type polycrystalline silicon film and the tungsten film can be prevented.

The third insulating film 73 is provided in the groove 82 to cover the second conductive film 35. A surface 73a of the third insulating film 73 may be substantially flat. The surface 73a of the third insulating film 73 is substantially the same in level as the upper surface 37a of the end portion 37 of the first conductive film 34. For example, a silicon oxide film (SiO₂ film) may be used as the third insulating film 73.

The fourth insulating film 74 is provided on the surface 73a of the third insulating film 73 and the end surface (e.g., the upper surface 37a) of the first conductive film 34. A surface 74a of the fourth insulating film 74 may be substantially flat. The surface 74a of the fourth insulating film 74 is substantially the same in level as the surface 69a of the second insulating film 69. An opening 85 is formed in the fourth insulating film 74. The surface 28a of the first impurity diffusion layer 28 is shown through the opening 85. For example, a silicon oxide film (SiO₂ film) may be used as the fourth insulating film 74.

The fifth insulating film 75 is provided on the surfaces 69a and 74a of the second and fourth insulating films 69 and 74 to be buried into the opening 85. For example, a silicon oxide film (SiO₂ film) may be used as the fifth insulating film 75.

The first contact plug 77 penetrates the fifth insulating film 75 provided in the opening 85. A lower end of the first contact plug 77 is in contact with the first impurity diffusion layer 28. Accordingly, the first contact plug 77 is electrically connected with the first impurity diffusion layer 28.

The second contact plug 78 penetrates the third to fifth insulating films 73 to 75. The bottom of the second contact plug 78 is in contact with the second impurity diffusion layer 29. Accordingly, the second contact plug 78 is electrically connected with the second impurity diffusion layer 29.

The third contact plug 79 penetrates the third to fifth insulating films 73 to 75 in a portion disposed on the gate electrode 33 and the second insulating film 69. The bottom of the third contact plug 79 is connected with the gate electrode 33. Accordingly, the third contact plug 79 is electrically connected with the gate electrode 33.

The semiconductor device 60 of the second embodiment configured as described above can have the same effects as the semiconductor device 10 of the first embodiment.

The vertical transistor 71 can have the desired characteristics and the difference of the characteristics among different products of the vertical transistor 71 can be suppressed.

The gate electrode 33 may also be used for the transistor 15 including the buried gate electrode (see FIG. 2), and for the vertical transistor 71 including the gate electrode formed on the outer circumferential side surface 66b of the pillar 66.

The semiconductor device 60 of the second embodiment may be used for the dynamic random access memory (DRAM) having memory cells configured in the 6F² or 4F² layout.

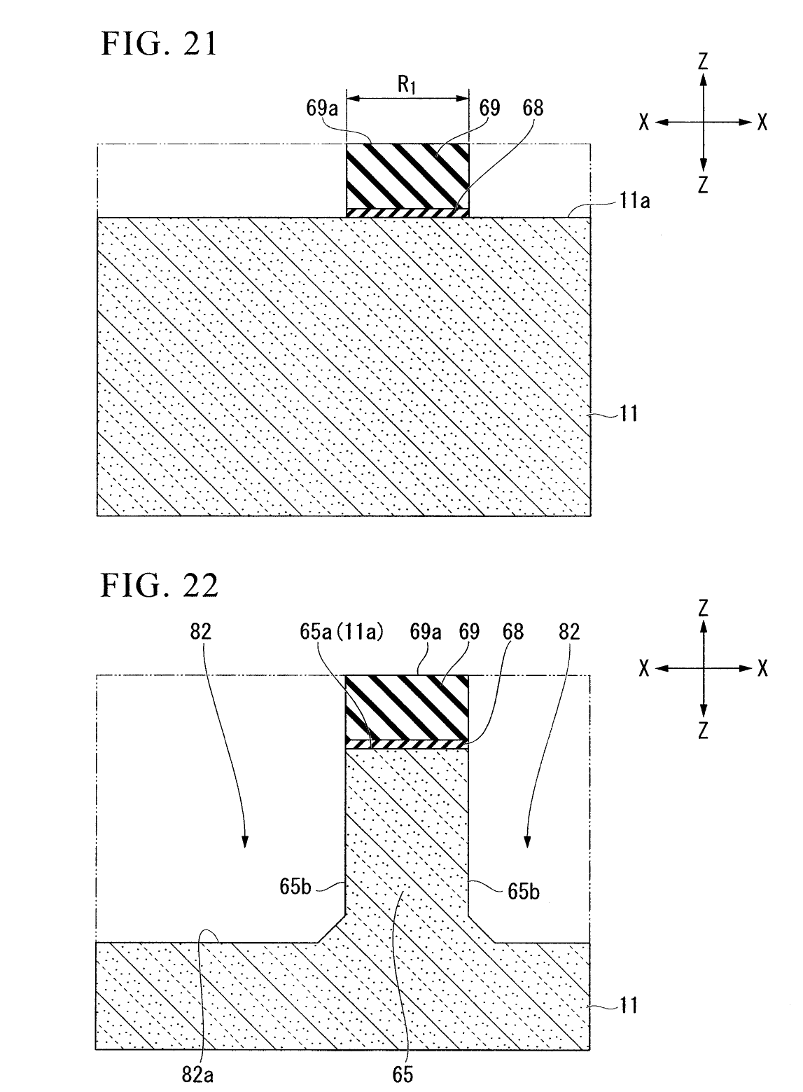

FIGS. 21 to 31 are fragmentary cross sectional elevation views illustrating a transistor in steps involved in a method of forming a semiconductor device according to the second embodiment of the present invention. FIGS. 21 to 31 are fragmentary cross sectional elevation views corresponding to the fragmentary cross sectioned view of the semiconductor device 60 in FIG. 18. In FIGS. 21 to 31, the same components as those of the semiconductor device 60 are assigned with the same reference numerals. In the cross sectioned views of the structure in FIGS. 21 to 31, illustration will be omitted for the pillar 66, the first insulating film 68, and the second insulating film 69 shown in FIGS. 19 and 20, and the third contact plug 79, which are shown in FIG. 20.

A method of forming the semiconductor device 60 of the second embodiment will be described with reference to FIGS. 21 to 31.

In a process shown in FIG. 21, for example, a P-type silicon substrate is prepared as the semiconductor substrate 11. A concentration of boron, which is P-type impurities, in the semiconductor substrate 11 may be, but is not limited to, 1.0×10¹⁷ atoms/cm³. Then, the first insulating film 68 (e.g., a silicon oxide film (SiO₂ film) having a thickness of 10 nm) and the second insulating film 69 (e.g., a silicon nitride film (SiN film) having a thickness of 100 nm) are sequentially stacked on the surface 11a of the semiconductor substrate 11.

Then, a patterned photoresist (not shown) is formed on the surface 69a of the second insulating film 69. The first and second insulating films 68 and 69 are etched using the photoresist as a mask to form the first and second patterned insulating films 68 and 69 shown in FIG. 21. The photoresist (not shown) is then removed.

A diameter R₁ of the second patterned insulating film 69 may be, but is not limited to, 60 nm. The diameter R₁ of the second insulating film 69 may be properly selected according to desired characteristics of the vertical transistor 71.

Further, in the process shown in FIG. 21, the isolation region, which is not shown, is formed by a known technique.

Then, in a process shown in FIG. 22, the semiconductor substrate 11 is etched by an anisotropic etching process (e.g., dry etching process) using the second insulating film 69 as a mask to form the groove 82. A plurality of pillars 65 and a plurality of pillars 66 are formed around the groove 82.

In this case, the first and second patterned insulating films 68 and 69 are formed on the isolation region (not shown). An insulating film (e.g., a silicon oxide film (SiO₂ film)) forming the isolation region (not shown) is patterned by an etching process using the first and second insulating films 68 and 69 as masks to form the pillar (not shown) formed of an insulating film.

A depth of the groove 82 from the surface 11a of the semiconductor substrate 11 may be, but is not limited to, 120 nm.

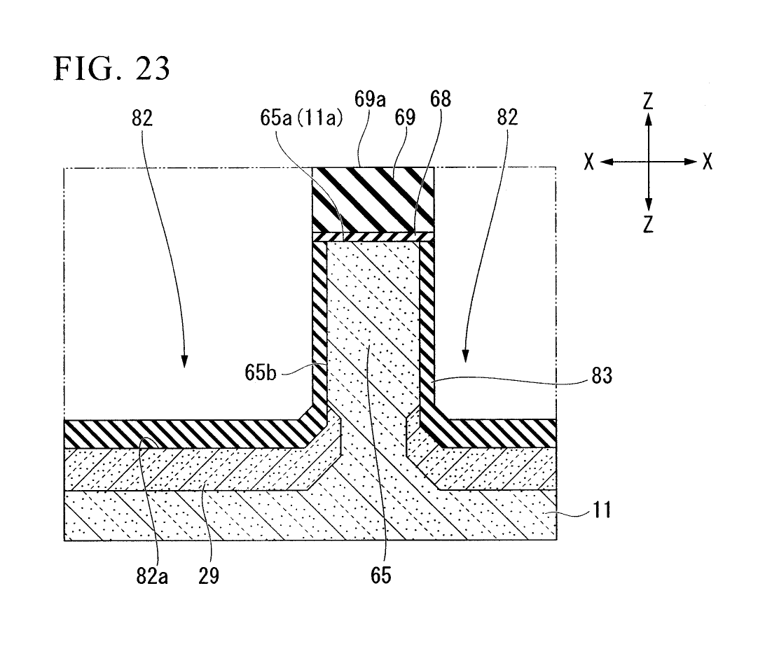

In a process shown in FIG. 23, a silicon oxide film (SiO₂ film) with a thickness of, for example, 5 nm, which is not shown, is formed to cover the side surface 65b of the plurality of pillars 65, the side surface 66b of the plurality of pillars 66 (not shown), and the bottom 82a of the groove 82. Arsenic is ion-implanted into the semiconductor substrate 11 with energy of 20 KeV and a concentration of 1.0×10¹⁵ atoms/cm³ through the silicon oxide film. The semiconductor substrate 11 is then heated at a temperature of 900° C. for 10 seconds, such that the second impurity diffusion layer 29 is formed in the vicinity of the bottom 82c of the groove 82.

A silicon oxide film (SiO₂ film) with a thickness of, for example, 20 nm is then formed on the second impurity diffusion layer 29 by a high density plasma (HDP) method.

The silicon oxide film (SiO₂ film) with a thickness of, for example, 5 nm, which is not shown, is removed. A thermal oxide film (SiO₂ film) with a thickness of, for example, 5 nm is formed to cover the side surface 65b of the plurality of pillars 65, the side surface 66b of the plurality of pillars 66 (not shown), and the bottom 82a of the groove 82. Accordingly, the gate insulating film 83 including the thermal oxide film (SiO₂ film) with a thickness of, for example, 5 nm and the silicon oxide film with a thickness of, for example, 20 nm (both not shown) is formed. The gate insulating film 83 over the bottom 82c of the groove 82 is greater in thickness than other portion of the gate insulating film 83.

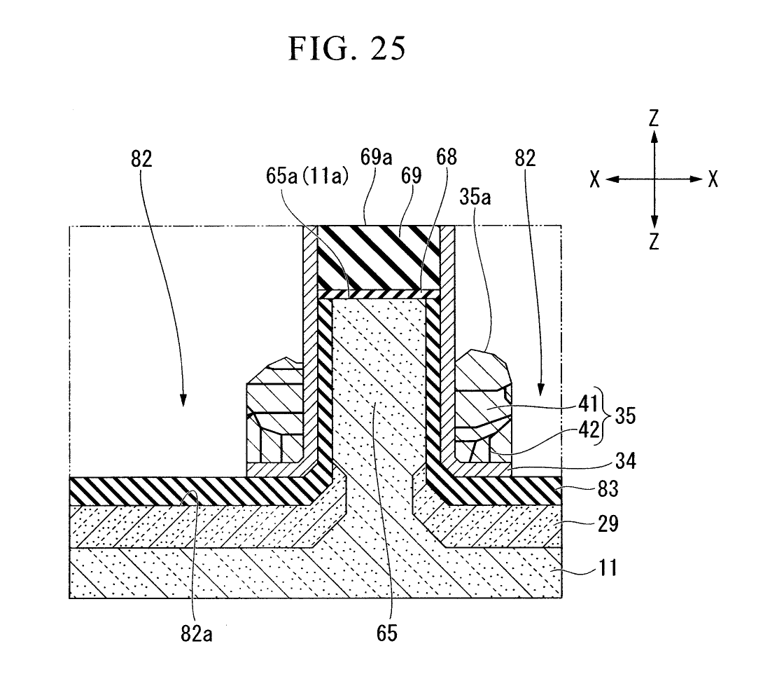

As described above, the greater thickness of the gate insulating film 83 over the bottom 82c of the groove 82 can prevent etching the second impurity diffusion layer 29 disposed lower than the gate insulating film 83 when the second conductive film 35 is etched in a process shown in FIG. 25 (the second conductive film etching process), which will be described below.

In order to increase the thickness of the gate insulating film 83, a thermal oxide film (SiO₂ film) having a thickness of, for example, 5 nm may be formed and then a silicon oxide film (SiO₂ film) may be deposited, for example, by a CVD method.

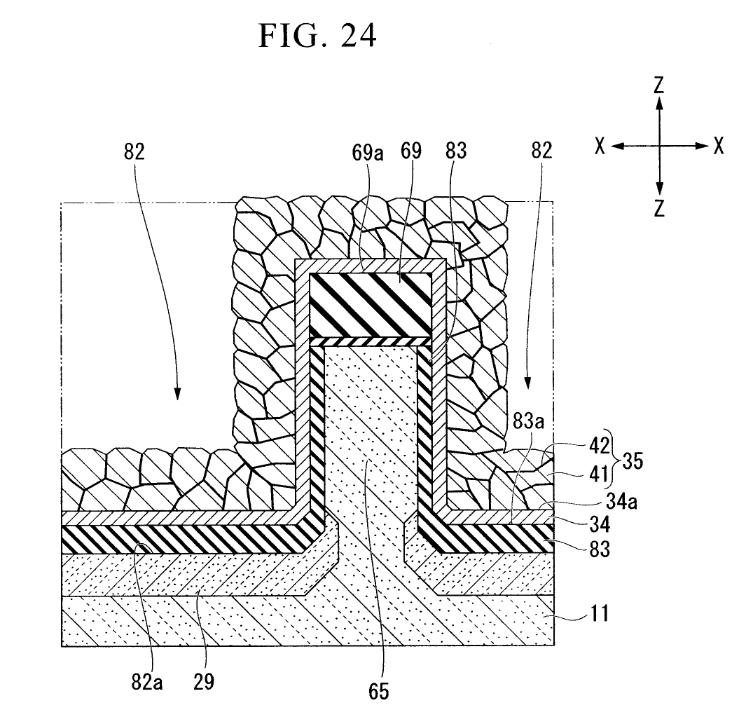

In the process shown in FIG. 24, the first conductive film 34 is formed to cover the surface 83 of the gate insulating film 83a and the second insulating film 69.

The first conductive film 34 shown in FIG. 24 is not yet etched. By etching the first conductive film 34 shown in FIG. 24, the first conductive film 34 with the end portion 37 shown in FIG. 18 is obtained. The first conductive film 34 may be formed by, but is not limited to, a CVD method.

A film functioning as a barrier film and facilitating control of a threshold voltage, which can be formed to a small thickness and easily etched, may be used as the first conductive film 35.

At least one of a polycrystalline silicon film which contains dopant impurities, a titanium nitride film, a tantalum nitride film, a molybdenum nitride film, a cobalt silicide film, and a nickel silicide film, may be used as the first conductive film 34. A stack of at least two films mentioned above may be also used as the first conductive film 34.

In the process of forming the first conductive film 34, the first conductive film 34 is formed with a smaller thickness than the second conductive film 35. Such a small thickness of the first conductive film 34 can ensure a uniform etching rate of the first conductive film 34.

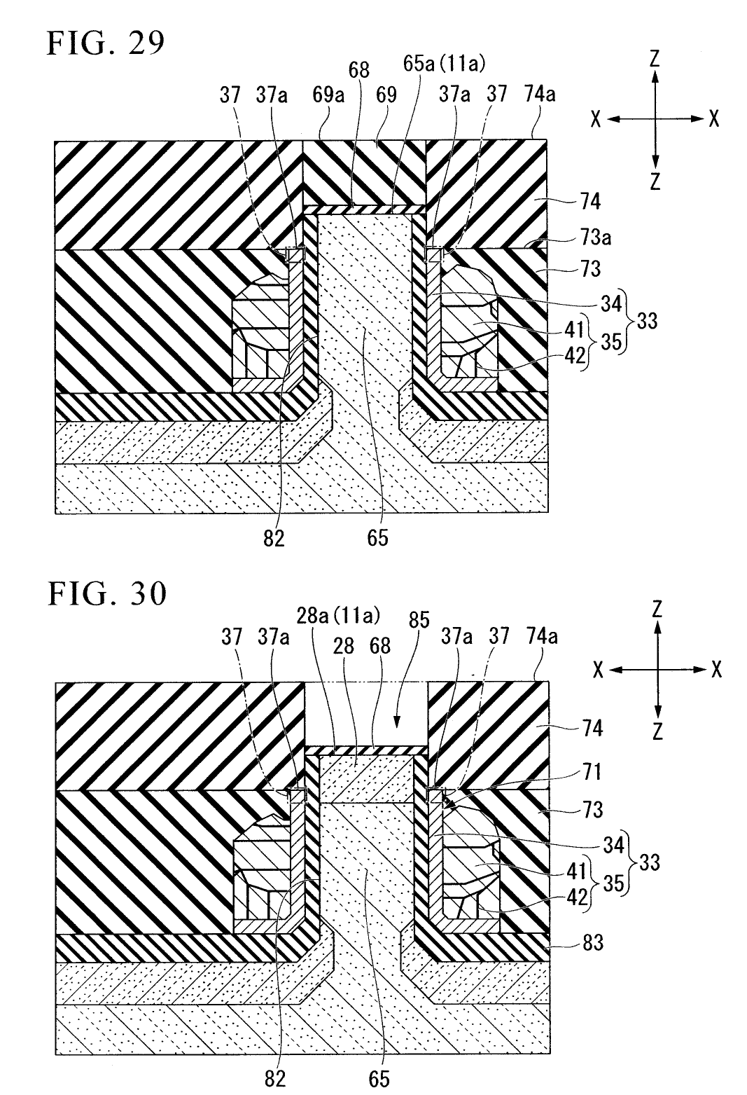

Accordingly, when the first conductive film 34 is etched in a process shown in FIG. 29, which will be described below, an etched surface of the first conductive film 34 (the upper surface 37a of the first conductive film 34) can be processed to be a substantially uniform level. Also, etching the first conductive film 34 in the depth direction of the groove 82 can be easily controlled.

Accordingly, the variation of the etching rate in the etching process of the first conductive film 34 among a plurality of vertical transistors 71 is reduced. The difference of the depth from the surface 11a of the semiconductor substrate 11 to the upper surface 37a of the first conductive film 34 provided in the plurality of vertical transistors 71 can be suppressed. Therefore, the difference of the characteristics among different products of the vertical transistor 71 can be suppressed.

The second conductive film 35 is then formed to cover the surface 34a of the first conductive film 34. The second conductive film 35 may be formed by, but is not limited to, a CVD method. The second conductive film 35 shown in FIG. 24 is not yet etched. By etching the second conductive film 35 shown in FIG. 24, the second conductive film 35 shown in FIG. 18 is obtained.

The second conductive film 35 is smaller in resistance than the first conductive film 34. The second conductive film 35 reduces the resistance of the gate electrode 33. The second conductive film 35 is greater in thickness than the first conductive film 34. After the second conductive film 35 shown in FIG. 24 is etched in a process shown in FIG. 25, which will be described below, the upper surface 35a of the second conductive film 35 is non-flat due to a non-uniform etching rate of the etching process, as described in the first embodiment.

One of a cobalt silicide film, a nickel silicide film, a tungsten film, a molybdenum film, a cobalt film, a nickel film, a copper film, and an aluminum film may be used as the second conductive film 35.

In order to prevent reaction between the first conductive film 34 and the second conductive film 35, a process of forming the third conductive film 52 on the surface 34a of the first conductive film 34 may be provided between the first conductive film forming process and the second conductive film forming process.

In some cases, an N-type polycrystalline silicon film having a work function of, for example, 4.05 eV (e.g., an N-type polycrystalline silicon film with a thickness of 5 nm, in which arsenic of 2.0×10²⁰ atoms/cm³ is doped) is formed as the first conductive film 34. A tungsten film (e.g., with a thickness of 20 nm) is formed as the second conductive film 35. A titanium nitride film (e.g., with a thickness of 2 nm) may be formed as the third conductive film 52 (not shown).

In some cases, a P-type polycrystalline silicon film may be used as the first conductive film 34 in place of the N-type polycrystalline silicon film.

In a process shown in FIG. 25, the second conductive film 35 shown in FIG. 24 is selectively etched by an anisotropic etching process (e.g., a dry etching process) under an etching condition of a high selectivity ratio of the second conductive film 35 with respect to the first conductive film 34. The second conductive film 35 with the non-flat upper surface 35a is formed.

In the second conductive film etching process, the average depth from the surface 11a of the semiconductor substrate 11 to the upper surface 35a of the second conductive film 35 may be, but is not limited to, 60 nm.

A portion of the first conductive film 34 formed on the surface 69a of the second insulating film 69 and a portion of the first conductive film 34 formed on the bottom 82a of the groove 82 but not covered with the second conductive film 35 are selectively removed by the etching process.

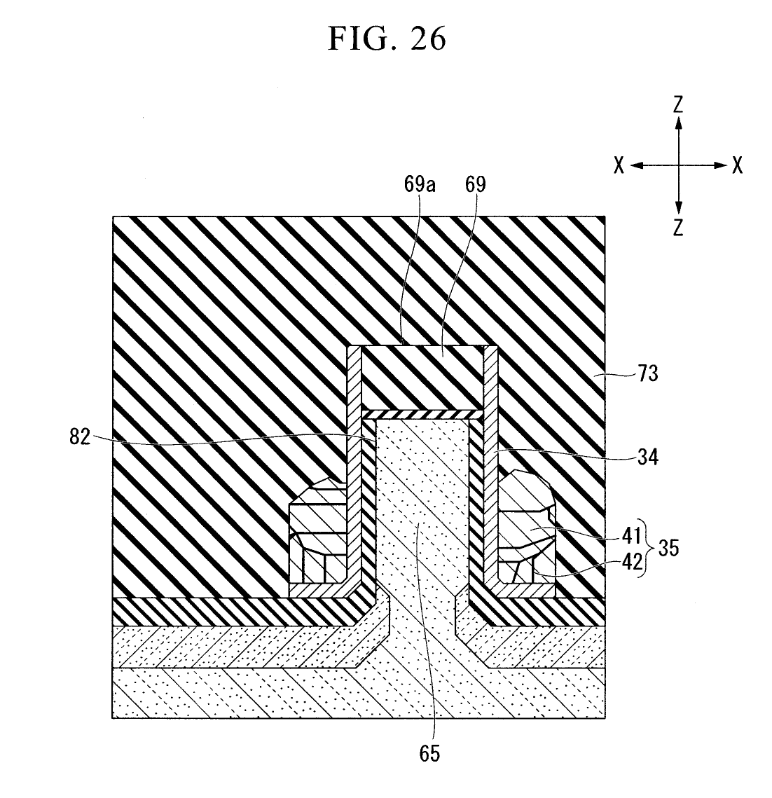

In a process shown in FIG. 26, the third insulating film 73 is formed with an enough thickness to be buried in the groove 82 and to cover an upper surface of the structure shown in FIG. 25. The third insulating film 73 may be formed by, but is not limited to, a CVD method. The third insulating film 73A may be, but is not limited to, a silicon oxide film (SiO₂ film) with a thickness of 200 nm.

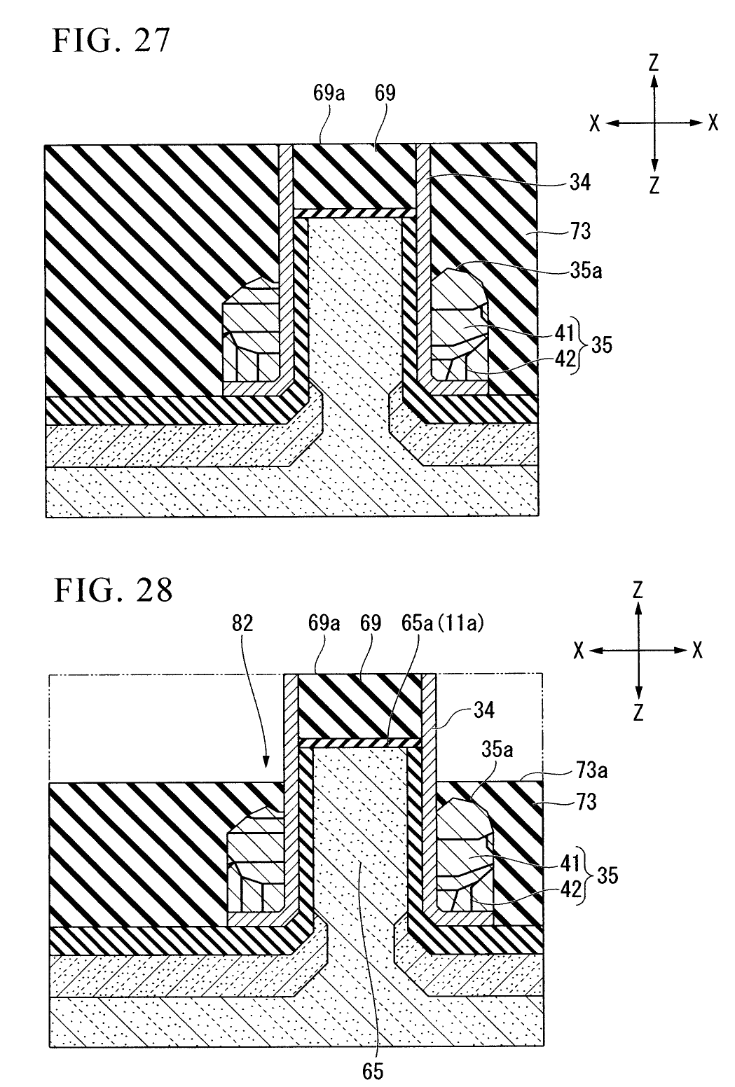

In a process shown in FIG. 27, the third insulating film 73 is polished by a CMP method until the surface 69a of the second insulating film 69 and the upper end of the first conductive film 34 are shown, to planarize an upper surface of the structure shown in FIG. 27.

In a process shown in FIG. 28, the third insulating film 73 shown in FIG. 27 is etched to form the third insulating film 73 with the flat surface 73a shown in FIG. 18 described above.

A depth from the surface 11a of the semiconductor substrate 11 to the surface 73a of the third insulating film 73 may be, but is not limited to, 20 nm.

In a process shown in FIG. 29, a portion of the first conductive film 34 formed on the side surfaces 65b and 66b of the plurality of pillars 65 and 66 is etched by etching process using the third insulating film 73 as a mask. The portion of the first conductive film 34 extends in the depth direction of the groove 82. The portion of the first conductive film 34 is not covered by the surface 73a of the third insulating film 73. The first conductive film 34 has an etched upper surface 37a defining an end portion 37. The end portion 37 protrudes from the upper surface 35a of the second conductive film 35 after the etching process has been performed.

Accordingly, the gate electrode 33 common to the pillars 65 and 66 is formed. In the process shown in FIG. 29, the end portion 37 of the first conductive film 34 is formed to face the first impurity diffusion layer 28 shown in FIG. 18.

The first conductive film 34 is etched while the second conductive film 35 is covered with the third insulating film 73, thereby suppressing the heavy-metal atoms contained in the second conductive film 35 from being diffused into the semiconductor substrate 11. The heavy-metal atoms adversely affect the characteristics of the vertical transistor 71.

Accordingly, since an increase of junction leakage current can be suppressed, a plurality of vertical transistors 71 can have desired characteristics.

The isotropic etching process or the anisotropic etching process may be used to etch the first conductive film 34. For example, a wet etching process or a dry etching process may be used as an isotropic etching process. For example, a dry etching process may be used as anisotropic etching process.

In some cases, the first conductive film 34 is wet-etched by twice the thickness thereof, that is, an over-etching amount is 100%. In this case, the upper surface 37a of the first conductive film 34 is disposed about 15 nm lower in level than the surface 73a of the third insulating film 73. The average depth from the upper surface 37a of the first conductive film 34 to the upper surface 35a of the second conductive film 35 is 35 nm.

In case, the third conductive film 52 and the first conductive film 34 may be selectively removed together by the etching process.

The fourth insulating film 74 having the surface 74a that is substantially the same in level as the surface 69a of the second insulating film 69 is formed on the surface 73a of the third insulating film 73 and the upper surface 37a of the first conductive film 34. For example, a silicon oxide film (SiO₂ film) may be used as the fourth insulating film 74.

In a process shown in FIG. 30, the second insulating film 69 shown in FIG. 29 is removed to form the opening 85 through which the first insulating film 68 is partially shown. Arsenic is then introduced into the end surface 65a of the pillar 65 shown in FIG. 29 (the surface 11a of the semiconductor substrate 11) through the first insulating film 68 (e.g., with energy of 20 KeV and an implantation amount of 1.0×10¹⁵ atoms/cm³). In some cases, arsenic may be ion-implanted in to the end surface 65a of the pillar 65. The semiconductor substrate 11 is then heated at a temperature of 900° C. for 10 seconds for implantation damage recovery. The first impurity diffusion layer 28 is formed in the pillar 65.

The first impurity diffusion layer 28 is formed to face the end portion 37 of the first conductive film 34 while the gate insulating film 83 is interposed between the first impurity diffusion layer 28 and the end portion 37 of the first conductive film 34. The depth of the first impurity diffusion layer 28 from the surface 11a of the semiconductor substrate 11 may be, but is not limited to, 45 nm. Thus, the vertical transistor 71 is formed.

Only one of the vertical transistors 71 formed in the semiconductor substrate 11 is shown in FIG. 30.

The threshold voltage of the vertical transistor 71 may be adjusted as follows. After arsenic is introduced, an appropriate amount of boron may be introduced into the surface 11a of the semiconductor substrate 11 into which arsenic has been ion-implanted.

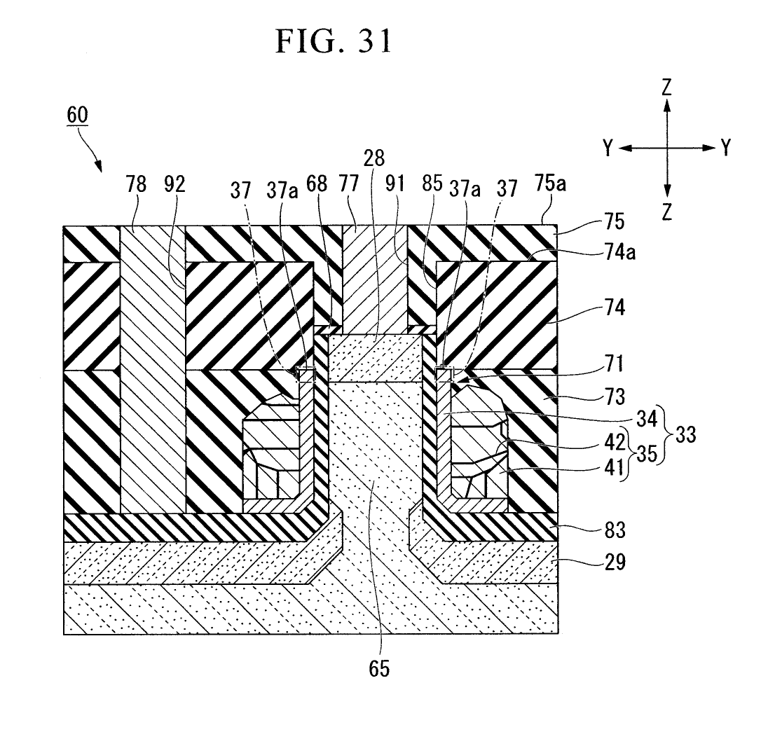

In a process shown in FIG. 31, the fifth insulating film 75 is formed on the surface 74a of the fourth insulating film 74 so that the fifth insulating film 75 fills the opening 85. The fifth insulating film 75 may be formed by, but is not limited to, a CVD method. For example, a silicon oxide film (SiO₂ film) with a thickness of 100 nm may be used as the fifth insulating film 75.

Then, a patterned photoresist (not shown) is formed on the surface 75a of the fifth insulating film 75. The second insulating film 69 and the fifth insulating film 75 are etched using the photoresist as a mask to form the opening 91. The first impurity diffusion layer 28 is shown through the opening 91. Then, the photoresist is removed.

The third to fifth insulating films 73 to 75 are then etched by the same method as the method of forming the opening 91, to form the opening 92. The second impurity diffusion layer 29 is shown through the opening 92.

The third to fifth insulating films 73 to 75 are then etched by the same method as the method of forming the opening 91, to form the opening (not shown) in which the third contact plug 79 (not shown) is formed.

A conductive film is buried in the openings 91 and 92 and the opening in which the third contact plug 79 is formed to form the first to third contact plugs 77 to 79. Thus, the semiconductor device 60 of the second embodiment is formed.

The method of forming the semiconductor device 60 of the second embodiment described above can have the same effects as the method of fabricating the semiconductor device 10 of the first embodiment.

The second conductive film 35 is selectively etched. The third insulating film 73 is formed to cover the second conductive film 35. The first conductive film 34 disposed higher in level than the upper surface 35a of the second conductive film 35 is selectively etched. Accordingly, the heavy-metal atoms, which adversely affect the characteristics of the vertical transistor 71, contained in the second conductive film 35 can be suppressed from reaching the gate insulating film 83 when the first conductive film 34 is etched. The upper surface 37a of the first conductive film 34 has a substantial uniformity or a reduced variation in level or in the depth direction of the groove 82.

Accordingly, the vertical transistor 71 having stable characteristics can be obtained and the difference of the characteristics among different products of the vertical transistor 71 can be suppressed.

Whereas the transistor is formed in the semiconductor substrate, the transistor may be formed in a semiconductor well region or other semiconductor regions. The term “a semiconductor region” may include, but is not limited to, the semiconductor substrate, a semiconductor well region or other semiconductor regions.

In the foregoing embodiments, the gate electrode is formed in the groove. In some cases, as shown in FIGS. 2 through 16, the groove may be formed in the semiconductor substrate. In other cases, as shown in FIGS. 17 through 31, the groove may be a space over the semiconductor substrate, wherein the space is defined by the pillars extending from the semiconductor substrate.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

Furthermore, the particular features, structures, or characteristics may be combined in any suitable manner in one or more embodiments.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. A semiconductor device comprising:
a semiconductor region having a groove;
a gate insulating film covering a surface of the groove; and
a gate electrode in the groove, the gate electrode comprising first and second conductive films, the first conductive film being in contact with the gate insulating film, the first conductive film having an upper surface which is higher than a close portion of the second conductive film, the close portion being closer to the upper surface of the first conductive film.

2. The semiconductor device according to claim 1, wherein the first conductive film is interposed between the gate insulating film and the second conductive film.

3. The semiconductor device according to claim 2, further comprising:
an insulating film in the groove, the insulating film covering the second conductive film.

4. The semiconductor device according to claim 3, wherein the upper surface of the first conductive film has a substantially uniform level.

5. The semiconductor device according to claim 4, wherein a top of the second conductive film is lower than the upper surface of the first conductive film.

6. The semiconductor device according to claim 5, wherein an upper surface of the insulating film is substantially the same in level as the upper surface of the first conductive film.

7. The semiconductor device according to claim 1, wherein the second conductive film is lower in resistivity than the first conductive film.

8. The semiconductor device according to claim 1, wherein the first conductive film comprises first and second portions,
wherein the first and second portions are positioned at opposite sides of the first conductive film,
wherein a first upper surface of the first portion is substantially the same in level as a second upper surface of the second portion.

9. The semiconductor device according to claim 1, wherein the second conductive film is greater in horizontal dimension than the first conductive film.

10. The semiconductor device according to claim 1, wherein an upper surface of the second conductive film is non-flat.

11. The semiconductor device according to claim 10, wherein the second conductive film has crystal grains and grain boundaries.

12. The semiconductor device according to claim 1, further comprising:
a first impurity diffusion layer in the semiconductor region, the first impurity diffusion layer being adjacent to the groove, the first impurity diffusion layer having a top portion and a bottom portion, the upper surface of the first conductive film being higher than the bottom portion and lower than the top portion.

13. The semiconductor device according to claim 1, further comprising:
a third conductive film between the first and second conductive films.

14. A semiconductor device comprising:
a semiconductor region having a groove;
a gate insulating film covering a surface of the groove;
a gate electrode in the groove, the gate electrode comprising first and second conductive films, the first conductive film being in contact with the gate insulating film, the first conductive film comprising an upper portion, the upper portion having an upper side surface; and
an insulating film covering the second conductive film, the insulating film having a first side surface which faces to the upper side surface.

15. The semiconductor device according to claim 14, wherein an upper surface of the insulating film is substantially the same in level as an upper surface of the first conductive film.

16. The semiconductor device according to claim 14, wherein an upper surface of the second conductive film is non-flat.

17. The semiconductor device according to claim 14, wherein the second conductive film is greater in horizontal dimension than the first conductive film.

18. A semiconductor device comprising:
a semiconductor region having a semiconductor side surface; and
a gate electrode comprising first and second conductive films, the first conductive film extending along the semiconductor side surface, the second conductive film being disposed near the first conductive film, a top of the first conductive film being higher than a top of the second conductive film.

19. The semiconductor device according to claim 18, further comprising:
an insulating film in the groove, the insulating film covering the second conductive film.

20. The semiconductor device according to claim 19, wherein an upper surface of the insulating film is substantially the same in level as an upper surface of the first conductive film.
